(19) United States
(12) Patent Application Publication
(10) Pub. No.: US 2007/0059929 A1
(43) Pub. Date: Mar. 15, 2007

(54) Method of forming a tantalum carbon nitride layer and method of manufacturing a semiconductor device using the same

(76) Inventors: Hag-Ju Cho, Seoul (KR); Sang-Bom Kang, Seoul (KR); Seong-Geon Park, Gyeonggi-do (KR); Taek-Soo Jeon, Gyeonggi-do (KR); Hye-Lan Lee, Gyeonggi-do (KR); Yu-Gyun Shin, Gyeonggi-do (KR)

Correspondence Address: MYERS BIGEL SIBLEY & SAJOVEC, PO BOX 37428, RALEIGH, NC, 27627, US

(21) Appl. No.: 11/438,941

(22) Filed: May 23, 2006

Related U.S. Application Data
(63) Continuation-in-part of application No. 10/877,848, filed on Jun. 25, 2004, now Pat. No. 7,081,409.

(30) Foreign Application Priority Data
May 24, 2005 (KR) 2005-43696

(51) Int. Cl. H01L 21/44

(52) U.S. Cl. 438/681; 438/680; 438/685; 438/653; 438/656; 257/E21.295

(57) ABSTRACT

In some embodiments of the present invention, methods of forming a tantalum carbon nitride layer include introducing a source gas including a tantalum metal complex onto a substrate, wherein one or more of the ligands of the tantalum metal complex include nitrogen and one or more of the ligands of the tantalum metal complex include carbon; and thermally decomposing the tantalum metal complex to form a tantalum carbon nitride layer on the substrate. In some embodiments, the tantalum metal complex includes Ta(NR₁)(NR₂R₃)₃, wherein R₁, R₂ and R₃ are each independently H or a C₁-C₆ alkyl group. In some embodiments, the tantalum metal complex may be [Ta(═NC(CH₃)₂C₂H₅)(N(CH₃)₂)₃]. Methods of forming a gate structure, methods of manufacturing dual gate electrodes and methods of manufacturing a capacitor including tantalum carbon nitride are also provided herein.

### CLAIM OF PRIORITY

This application is a continuation-in-part of U.S. patent application Ser. No. 10/877,848, filed on Jun. 25, 2004 the contents of which are herein incorporated by reference in their entirety. This application also claims priority under 35 USC § 119 to Korean Patent Application No. 200543696 filed on May 24, 2005, the contents of which are herein incorporated by reference in their entirety.

### FIELD OF THE INVENTION

The present invention relates to methods of forming tantalum carbon nitride layers and methods of manufacturing semiconductor devices using the same.

### BACKGROUND OF THE INVENTION

Conventionally, transistors in semiconductor devices have included a gate electrode formed on an active region of a semiconductor substrate, a gate insulation layer formed between the substrate and the gate electrode and source/drain regions formed adjacent to the gate electrode. In addition, current semiconductor devices generally include a metal oxide semiconductor field effect transistor (MOSFET) having a gate insulating layer formed on the semiconductor substrate and a gate electrode formed on the gate insulating layer. To increase response speed and decrease power consumption, the semiconductor device may include a complementary metal oxide semiconductor (CMOS) transistor that has an N-type MOS (NMOS) transistor and a P-type MOS (PMOS) transistor.

The NMOS and the PMOS transistors may have gate electrodes formed from identical conductive materials, so as to simplify CMOS transistor manufacturing processes. For example, N-type doped polysilicon may be used in the formation of the gate electrodes of the NMOS and the PMOS transistors. The gate insulation layers of the NMOS and the PMOS transistors may be formed, for example, by using silicon oxide layers and a thermal oxidation process.

In order to increase the response speed of semiconductor devices, it may be desirable to decrease the thickness of the gate insulation layer of the transistor. However, when the gate insulation layer is less than a critical thickness, the leakage current through the gate insulation layer may be greatly increased, which may degrade the electrical properties of the semiconductor device. Thus, silicon oxide layers may not be advantageously employed as gate insulation layers of transistors because the thickness of the silicon oxide layer may not be able to be further reduced using current semiconductor manufacturing technology. Therefore, high dielectric constant dielectric layers (hereinafter, referred to as a high-k dielectric layers) have been studied as gate insulation layers in transistors.

A high-k dielectric layer may have relatively low current leakage despite having an equivalent oxide thickness (EOT) substantially less than the critical thickness of a silicon oxide layer. The EOT of the high-k dielectric layer refers to the thickness of a silicon oxide layer having an equivalent capacitance. Thus, use of a high-k dielectric layer may provide a capacitance equivalent to that provided by a physically thinner silicon oxide layer while providing improved current leakage characteristics.

When an N-type doped polysilicon layer is used as a gate electrode formed on a high-k dielectric layer acting as a gate insulation layer, the doped polysilicon layer may react with the high-k dielectric layer so that the threshold voltage of the transistor may be irregular compared to a transistor having a gate insulation layer of silicon oxide. Specifically, a PMOS transistor having a polysilicon gate electrode may have a large threshold voltage in accordance with the increase in the work function of the polysilicon. Additionally, Fermi-level pinning phenomenon may occur in the PMOS transistor because the polysilicon gate electrode Fermi-level may not vary despite having impurities doped into the polysilicon gate electrode.

A depletion layer may be formed adjacent to a polysilicon gate electrode when the MOS transistor that includes a gate electrode is in an inversion mode. Hence, the effective thickness of the gate insulation layer of the MOS transistor may increase in accordance with the depletion layer, thereby reducing the effective capacitance of the MOS transistor in an inversion mode compared to that of the MOS transistor in a storage mode.

Considering the above-mentioned problems, high-k gate electrode materials for MOS transistors should provide a sufficient threshold voltage. However, optimal gate electrode materials that use conventional etching or deposition processes and are relatively inexpensive have not yet been developed.

Meanwhile, MOS transistors are generally divided into NMOS transistors and PMOS transistors in accordance with the type of carriers of each. The NMOS transistor uses electrons as the main carriers, whereas in PMOS transistors, holes are the main carriers. Thus, a gate electrode of a PMOS transistor may have a work function higher than that of a gate electrode of an NMOS transistor. As a result, manufacturing processes for forming PMOS and NMOS transistors may be complicated.

FIGS. 1 to 3 are cross-sectional views illustrating a conventional method of manufacturing dual gates in a semiconductor device.

Referring to FIG. 1, after an isolation layer 2 is formed on a semiconductor substrate 1, a first channel region 3 and a second channel region 4 are formed at upper portions of the substrate 1 by doping impurities into the upper portions of the substrate 1. The first channel region 3 and the second channel region 4 may be formed using P-type impurities and N-type impurities, respectively.

A first gate insulation layer 5 is formed on the first and the second channel regions 3 and 4. A first gate electrode layer 6 is formed on the first gate insulation layer 5 and on the isolation layer 2.

Referring to FIG. 2, the first gate electrode layer 6 and the first gate insulation layer 5 are sequentially etched to form a first gate electrode 6a of an NMOS transistor. The first gate electrode 6a is positioned on the first channel region 3.

A second gate insulation layer 7 is formed on the first and the second channel regions 3 and 4 to cover the first gate electrode 6a. A second gate electrode layer 8 is formed on the second gate insulation layer 7 and the isolation layer 2. The second gate electrode layer 8 includes a second material that has a work function higher than the work function of the first material in the first gate electrode layer 6.

Referring to FIG. 3, a second gate electrode 8a of a PMOS transistor is formed on the second channel region 4 by successively etching the second gate electrode layer 8 and the second gate insulation layer 7. Since the first gate electrode 6a of the NMOS transistor may be damaged during this etching process, the NMOS transistor including the damaged first gate electrode 6a may have undesirable electrical characteristics. When the first and the second gate electrodes 6a and 8a are formed by a damascene process, the manufacturing processes for forming the first and the second gate electrodes 6a and 8b may be more complicated.

In order to provide desirable electrical properties, the gate electrode of the NMOS transistor may include a material having a work function that is different from that of the material in the gate electrode of the PMOS transistor. Further, NMOS and PMOS gate insulation layers may not exhibit the Fermi-level pinning phenomenon when the gate insulation layers are formed from high-k dielectric materials.

Typically, a unit cell of a dynamic random access memory (DRAM) device includes one access transistor and one storage capacitor. As the DRAM device is highly integrated, the size of the storage capacitor should be minimized while retaining a relatively large storage capacitance.

To improve the capacitance of the capacitor, a dielectric layer may either be formed from a high-k dielectric material or the effective area of the capacitor may be increased. Further, the capacitance of the capacitor may be enhanced by reducing the thickness of the dielectric layer.

Recently, high-k dielectric materials such as metal oxides have been used as dielectric layers in capacitors. Examples of metal oxides include Ta₂O₅, TiO₂, Al₂O₃, Y₂O₃, ZrO₂, HfO₂, BaTiO₃, SrTiO₃ and the like. For example, U.S. Pat. No. 5,316,982 (issued to Taniguchi) describes a capacitor having a dielectric layer formed using a metal oxide. However, the metal oxide in the dielectric layer may react with the material in the lower or upper electrode of the capacitor, which may deteriorate the electrical characteristics of the capacitor. Specifically, the oxygen in the metal oxide may react with silicon contained in a lower or upper polysilicon electrode. Thus, a silicon oxide interface layer may be formed between the dielectric layer and the lower or upper electrode, thus reducing the dielectric constant of the dielectric layer. As a result, the electrical characteristics of the capacitor may be deteriorated due to the silicon oxide interface layer and the lower dielectric constant. When a semiconductor device such as a DRAM device includes such as capacitor, the semiconductor device may have poor reliability. Further, when the upper or lower electrode has a low work function, the energy barrier between the dielectric layer and the upper or lower electrode may decrease, thereby increasing current leakage from the capacitor. Therefore, the electrode of the capacitor preferably includes a material that does not react with the dielectric layer, thus minimizing current leakage from the capacitor.

Methods of forming tantalum nitride layers for use in electrodes are described in U.S. Pat. No. 6,204,204 (issued to Paranjpe et al.), U.S. Pat. No. 6,153,519 (issued to Jain et al.) and U.S. Pat. No. 5,668,054. For example, U.S. Pat. No. 5,668,054 describes a tantalum nitride layer formed by reacting terbutylimido-tris-diethylamido tantalum [Ta(═N^{t}Bu)(NEt₂)₃]; TBTDET] via a chemical vapor deposition (CVD) process. The tantalum nitride layer is formed at a temperature of above about 600° C. because the tantalum nitride layer may have a specific resistance of above about 10,000 μΩ-cm when the tantalum nitride layer is formed at a temperature below about 500° C.

An atomic layer deposition (ALD) process for forming tantalum nitride layers has also been developed. When the tantalum nitride layer is formed by an ALD process, the tantalum nitride layer may generally be formed at temperatures lower than that of the CVD process. In addition, the tantalum nitride layer formed by ALD may have step coverage superior to that of a tantalum nitride layer formed by a CVD process. For example, a method of forming a tantalum nitride layer by an ALD process is described in U.S. Pat. No. 6,203,613 (issued to Gates).

U.S. Pat. No. 6,537,901 (issued to Cha et al.) describes a method of forming a transistor in a semiconductor device whereby a first gate insulation layer and a second gate insulation layer are formed on a substrate in which an NMOS transistor area and a PMOS transistor area have been defined. A first tantalum layer or a first tantalum nitride layer having a work function of about 4.0 to about 4.4 eV is formed on the first gate insulation layer in the NMOS transistor area. A second tantalum layer or a second tantalum nitride layer having a work function of about 4.8 to about 5.2 eV is formed on the second gate insulation layer in the PMOS transistor area. Metal layers with low specific resistances are formed on the first and second tantalum layers or the first and second tantalum nitride layers, respectively. The first and second tantalum layers or the first and second tantalum nitride layers are formed using tantalum precursors, such as TaCl, Ta(OCH), TDMAT, TDEAT, and the like.

U.S. Pat. No. 6,504,214 (issued to Yu et al.) describes a method of manufacturing a MOSFET with a high-k gate insulation layer, wherein the high-k is dielectric material is formed on a substrate with a buffer surface. A gate electrode is then formed on the gate insulation layer using tungsten, tantalum, titanium nitride or tantalum nitride. A gate contact electrode is formed on the gate electrode using a metal or metal silicide.

U.S. Pat. No. 6,492,217 (issued to Bai et al.) describes a method of forming a complementary metal gate, wherein a barrier layer is formed on a gate insulation layer using titanium nitride, tantalum silicon nitride or tantalum nitride after the gate insulation layer is formed on a semiconductor substrate. A gate electrode is then formed on the barrier layer.

U.S. Pat. No. 6,168,991 (issued to Choi et al.) describes a method of manufacturing a capacitor in a DRAM cell, wherein a first electrode is formed using tantalum, tantalum nitride or a combination thereof. A dielectric layer including a high-k dielectric material is then formed on the first electrode. A second electrode is formed on the dielectric layer using the same material as that of the first electrode.

Additionally, other methods of forming tantalum nitride layers are known, such as a method of forming a tantalum nitride layer through an ALD process using TaCl₅ as the tantalum source, and a method of forming a tantalum nitride layer through a CVD process using TBTDET at the tantalum source.

In the above-mentioned methods of forming tantalum nitride layers, however, several disadvantages may be result from the tantalum source used. For example, when the source includes TaCl₅, particles may be generated during the formation of the tantalum nitride layer and impurities, such as chlorine (Cl), may enter the tantalum nitride layer because the halogenated source has a solid phase. Other difficulties may also arise, such as when TBTDET is used, the deposition rate of the tantalum nitride layer may be very low due to the low vapor pressure of TBTDET.

Meanwhile, Japanese Laid-Open Patent Publication No. 2002-193981 describes a method of preparing tertiaryamylimido-tris-dimethylamido tantalum ([Ta(═NC(CH₃)₂C₂H₅)(N(CH₃)₂)₃]; TAIMATA®) and a metal organic chemical vapor deposition (MOCVD) process using a TAIMATA® precursor. According to the above Japanese Laid-Open Patent Publication, one mole of TaCl₅, four moles of LiNMe₂ and one mole of LiNH^{t}Am are reacted in an organic solvent at room temperature. The resultant solution is then filtered and dried to yield the TAIMATA® compound. The TAIMATA® compound is then dissolved in an organic solution that includes a nucleic acid. A tantalum nitride layer having a cubic crystalline structure may then be formed on a substrate through a CVD process using the TAIMATA® solution.

Korean Patent No. 449,782 describes a method of forming a thin film by an atomic layer deposition (ALD) process using a metal organic precursor or a tantalum halide precursor, wherein the reactants having vapor phases are provided onto a substrate loaded in a chamber so that a thin film having a low specific resistance may be formed at a low temperature.

The present inventors have filed Korean Laid-Open Patent Publication No. 2005-1262 entitled “METHOD OF FORMING ELECTRODE OF SEMICONDUCTOR DEVICE,” which is now pending in Korean Intellectual Property Office (KIPO). According to the above Korean Laid-Open Patent Publication, an electrode in a semiconductor device may be formed using a tantalum amine derivative as a precursor.

However, a simplified, relatively inexpensive method of forming a gate electrode that has a high work function is still needed to improve the electrical characteristics of NMOS and PMOS transistors.

### SUMMARY OF THE INVENTION

In some embodiments of the present invention, methods of forming a tantalum carbon nitride layer include introducing a source gas including a tantalum metal complex onto a substrate, wherein one or more of the ligands of the tantalum metal complex include nitrogen and one or more of the ligands of the tantalum metal complex include carbon; and thermally decomposing the tantalum metal complex to form a tantalum carbon nitride layer on the substrate.

In some embodiments of the present invention, the tantalum metal complex includes Ta(NR₁)(NR₂R₃)₃, wherein R₁, R₂ and R₃ are each independently H or a C₁-C₆ alkyl group. In some embodiments, the tantalum metal complex may include [Ta(═NC(CH₃)₂C₂H₅)(N(CH₃)₂)₃].

In some embodiments of the present invention, methods of forming a gate structure include forming a dielectric layer on a substrate; introducing a source gas including a tantalum metal complex onto the dielectric layer, wherein one or more of the ligands of the tantalum metal complex include nitrogen and one or more of the ligands of the tantalum metal complex include carbon; thermally decomposing the tantalum metal complex to form a tantalum carbon nitride layer on the dielectric layer; and forming a gate electrode on the dielectric layer by patterning the tantalum carbon nitride layer.

In some embodiments of the present invention, methods of manufacturing dual gate electrodes in a semiconductor device include forming a dielectric layer on a substrate having a PMOS transistor area and an NMOS transistor area; forming a first gate electrode on a first portion of the dielectric layer in the PMOS area of the substrate, wherein the first gate electrode includes a tantalum carbon nitride layer pattern and a first conductive layer pattern; and forming a second gate electrode on a second portion of the dielectric layer in the NMOS area of the substrate, wherein the second gate electrode includes a second conductive layer pattern, wherein the forming of the tantalum carbon nitride layer pattern includes introducing a source gas including a tantalum metal complex and thermally decomposing the tantalum metal complex, wherein one or more of the ligands of the tantalum metal complex include nitrogen and one or more of the ligands of the tantalum metal complex include carbon.

In some embodiments of the present invention, methods of manufacturing a capacitor include introducing a source gas comprising a tantalum metal complex onto a substrate, wherein one or more of the ligands of the tantalum metal complex include nitrogen and one or more of the ligands of the tantalum metal complex include carbon; thermally decomposing the tantalum metal complex to form a first electrode including a tantalum carbon nitride layer on the substrate; forming a dielectric layer on the first electrode; and forming a second electrode on the dielectric layer.

### BRIEF DESCRIPTION OF THE DRAWINGS

The above and other features and advantages of the present invention will become more apparent by describing in detailed example embodiments thereof with reference to the accompanying drawings, in which:

FIGS. 1 to 3 are cross-sectional views illustrating a conventional method of manufacturing dual gates in a semiconductor device;

FIG. 4 is a perspective view illustrating a gate structure according to some embodiments of the present invention;

FIGS. 5 to 9 are cross-sectional views illustrating methods of forming a gate structure according to some embodiments of the present invention;

FIG. 10 is a perspective view illustrating a gate structure according to some embodiments of the present invention;

FIGS. 11 to 13 are cross-sectional views illustrating methods of forming a gate structure according to some embodiments of the present invention;

FIGS. 14 to 18 are cross-sectional views illustrating methods of manufacturing dual gate structures in a semiconductor device according to some embodiments of the present invention;

FIGS. 19 to 23 are cross-sectional views illustrating methods of manufacturing dual gate structures in a semiconductor device according to some embodiments of the present invention;

FIGS. 24 to 28 are cross-sectional views illustrating methods of manufacturing dual gate structures in a semiconductor device according to some embodiments of the present invention;

FIGS. 29 to 33 are cross-sectional views illustrating methods of manufacturing a capacitor in a semiconductor device according to some embodiments of the present invention;

FIG. 34 is a graph illustrating leakage current densities of gate structures according to some embodiments of the present invention;

FIG. 35 is a graph illustrating leakage current densities of capacitors according to some embodiments of the present invention; and

FIG. 36 is a graph illustrating C-V characteristics of capacitors according to some embodiments of the present invention.

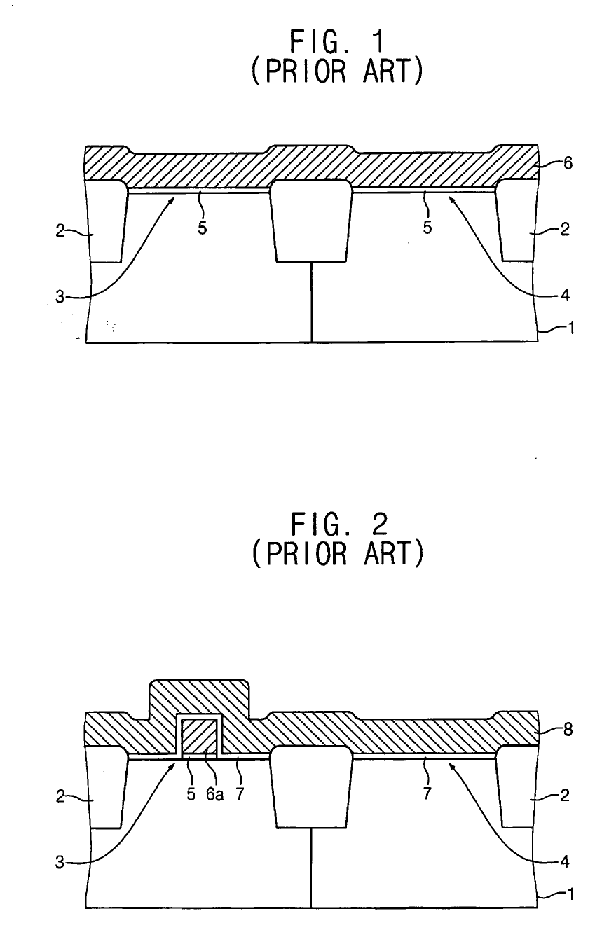

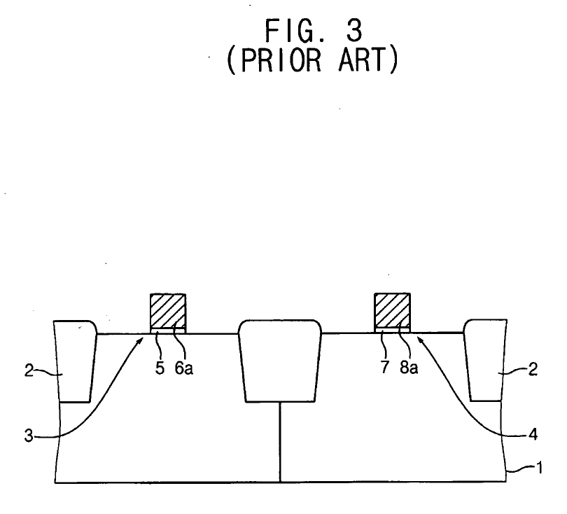

### DESCRIPTION OF THE EMBODIMENTS

The present invention is described more fully hereinafter with reference to the accompanying drawings, in which example embodiments of the present invention are shown. The present invention may, however, be embodied in many different forms and should not be construed as limited to the example embodiments set forth herein. Rather, these embodiments are provided so that this disclosure will be thorough and complete, and will fully convey the scope of the present invention to those skilled in the art. In the drawings, the sizes and relative sizes of layers and regions may be exaggerated for clarity.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like reference numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present invention are described herein with reference to cross-section illustrations that are schematic illustrations of idealized embodiments (and intermediate structures) of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Method of Forming a Tantalum Carbon Nitride Layer

According to some embodiments of the present invention, a source gas including a tantalum metal complex is introduced onto a substrate. The tantalum metal complex may include one or more ligands bound to a tantalum metal, wherein one or more of the ligands include nitrogen and one or more of the ligands include carbon. Thus, the tantalum metal complex may include an organometallic complex having one tantalum metal atom bound to ligands containing nitrogen and carbon. The tantalum metal complex may also include more than one tantalum metal atom. The tantalum metal complex may be thermally decomposed to form a tantalum carbon nitride (TaCN) layer on the substrate.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ may each independently be H or an alkyl group, such as a C₁-C₆ alkyl. Thus, R₁, R₂ and R₃ may be the same as one another or different from one another. The term C₁-C₆ alkyl, as used herein, is meant to refer to any alkyl having from 1 to 6 carbon atoms. In some embodiments of the present invention, the tantalum metal complex may be tertiaryamylimido-tris-dimethylamido tantalum [Ta(═NC(CH₃)₂C₂H₅)(N(CH₃)₂)₃] (TAIMATA®). When the tantalum metal complex includes TAIMATA®, the tantalum carbon nitride layer thus formed may have a work function in a range of about 4.6 eV to about 5.2 eV. Additionally, when the source gas includes TAIMATA®, a tantalum carbon nitride layer may be reproducibly formed on a substrate.

Hereinafter, methods of forming tantalum carbon nitride layers with a source gas including a tantalum metal complex, according to some embodiments of the present invention, will be described.

To deposit tantalum carbon nitride onto a substrate, a source gas that includes a tantalum metal complex may be provided onto the substrate together with a carrier gas. The carrier gas may include an inert gas. For example, the carrier gas may include argon, nitrogen, helium, and the like. Since the tantalum metal complex may have a liquid phase at room temperature, the source gas may be created by bubbling the carrier gas through the liquid phase of the tantalum metal complex. The vapor phase of the tantalum metal complex may then be introduced onto a substrate. The flow rate of the source gas provided onto the substrate may vary according to the flow rate of the carrier gas. As the flow rate of the source gas increases, the deposition rate of the tantalum carbon nitride layer may also increase.

During the formation of a tantalum carbon nitride layer on a substrate, according to some embodiments of the invention, a pressure control gas may be additionally provided into the chamber wherein the substrate is loaded. The pressure control gas may adjust the internal pressure of the chamber. The pressure control gas may include an inert gas, such as argon, helium, nitrogen, and the like. In some embodiments, the carrier gas may include an inert gas substantially the same as that of the pressure control gas. Alternatively, in some embodiments, the pressure control gas may include an inert gas different from that of the carrier gas. In some embodiments, the carrier gas and the pressure control gas may be introduced into the chamber through different gas supply lines.

In some embodiments, to thermally decompose the tantalum metal complex, the chamber may have a deposition temperature in a range of about 400° C. to about 700° C. and a deposition pressure in a range of about 0.01 Torr to about 100 Torr. When the deposition temperature is below about 400° C., the source gas may not be sufficiently thermally decomposed. When the deposition temperature is above about 700° C., the substrate and/or a semiconductor device including the tantalum carbon nitride layer may sustain thermal damage. In some embodiments of the invention, the deposition temperature is in a range of about 500° C. to about 650° C., and the deposition pressure is in a range of about 0.1 Torr to about 10 Torr.

When the tantalum metal complex is thermally decomposed, some of the Ta-ligand bonds may be broken by the thermal decomposition. That is, since the ligands may be bonded relatively weakly to the metal, they may be removed by heat applied during thermal decomposition. However, some of the tantalum and nitrogen in the tantalum metal complex may not be removed during thermal decomposition because the Ta═N double bond is relatively strong.

In practice, the ligands may remain partially bonded to the tantalum metal after the thermal decomposition so that a relatively large amount of carbon from the tantalum metal complex may remain in a thin layer formed on the substrate along with the Ta═N. As a result, a tantalum carbon nitride layer may be formed on the substrate.

The tantalum carbon nitride layer may have a work function considerably higher than a work function of a pure tantalum nitride layer. Specifically, the tantalum carbon nitride layer, according to an embodiment of the present invention, may have a relatively high work function in a range of about 4.6 eV to about 5.2 eV, whereas the pure tantalum nitride layer formed by a physical vapor deposition (PVD) process generally has a work function of about 4.4 eV. Therefore, the content of carbon in the tantalum carbon nitride layer may be the main parameter affecting the tantalum carbon nitride layer work function. In some embodiments of the present invention, the tantalum carbon nitride layer may include about 5 to about 50 percent by weight carbon based on the total weight of the tantalum carbon nitride.

To adjust a content of nitrogen in the tantalum carbon nitride layer, a first reaction gas including nitrogen may be additionally provided together with the source gas. The first reaction gas may include, for example, ammonia, nitrogen, diazene, and the like. The gases can be used alone or in any combination thereof.

A second reaction gas including carbon may be additionally provided together with the source gas so as to adjust the content of carbon in the tantalum carbon nitride layer. The second reaction gas may include, for example, methane, acetylene, and the like. The gases may also be used alone or in any combination thereof.

To facilitate the removal of the ligands of the tantalum metal complex, a third reaction gas may be provided together with the source gas. The third reaction gas may include, for example, hydrogen, silane, disilane and the like. The gases may be used alone or in any combination thereof. When the third reaction gas is introduced together with the source gas, the Ta-ligand bonds of the tantalum metal complex may be more easily broken so that the content of carbon in the tantalum carbon nitride layer may be reduced due to the increased concentration of Ta═N bonding in the tantalum carbon nitride layer. Therefore, tantalum carbon nitride layers having work functions of above about 5.0 eV generally are not formed when such third reaction gas is used.

The tantalum carbon nitride layer may also be treated using an activated gas. The activated gas may include, for example, one or more of ammonia, hydrogen, nitrogen, silane and disilane activated by a remote plasma process or a direct plasma process. Treatment of the tantalum carbon nitride layer using such an activated gas may decrease the level of impurities remaining on the surface of the tantalum carbon nitride layer.

When the tantalum carbon nitride layer is treated with activated hydrogen gas or an activated gas that includes hydrogen, the hydrogen may form relatively strong bonds with the carbon in the tantalum carbon nitride layer, thus removing some carbon from the tantalum carbon nitride layer. Thus, when an activated hydrogen gas or an activated gas that includes hydrogen is applied to a tantalum carbon nitride layer, the content of carbon in the tantalum carbon nitride layer may be reduced, thus increasing the content of nitrogen in the tantalum carbon nitride layer. As a result, the amount of carbon and nitrogen in the tantalum carbon nitride layer may be advantageously adjusted. However, the post-treatment processes described above may be omitted in some embodiments of the present invention.

Further, to control the work function and electrical characteristics of the tantalum carbon nitride layer, a material may be additionally doped into the tantalum carbon nitride layer. In some embodiments, this material may include oxygen or nitrogen.

As described above, in some embodiments of the invention, the tantalum carbon nitride layer may have a work function in a range of about 4.6 eV to about 5.2 eV. Thus, a tantalum carbon nitride layer according to an embodiment of the invention may be advantageously used as the gate electrode of a transistor, an electrode of a capacitor, various wirings of a semiconductor device, etc.

Gate Structure and Method of Manufacturing the Gate Structure

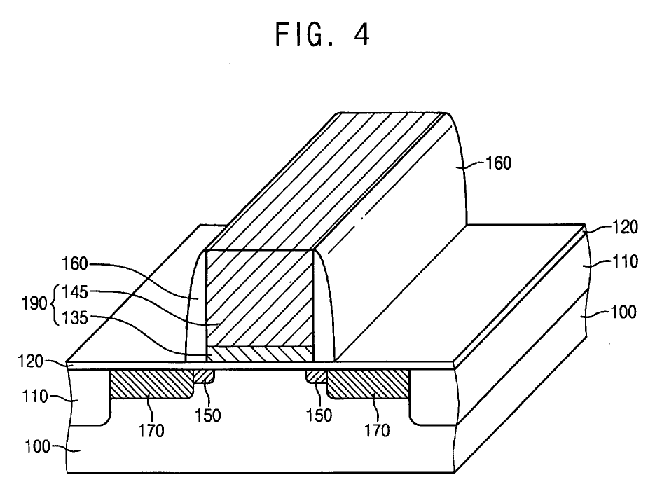

FIG. 4 is a perspective view illustrating a gate structure in accordance with some embodiments of the present invention. In some embodiments, the gate structure in FIG. 4 may be advantageously employed for a P-type metal oxide semiconductor (PMOS) transistor.

Referring to FIG. 4, an isolation layer 110 may be formed at an upper portion of a semiconductor substrate 100 to define an active region of the semiconductor substrate 100. A channel doping region (not shown) may be formed in the active region. The channel doping region may serve as the channel region of a transistor. In some embodiments, the channel doping region may be doped with N-type impurities.

A dielectric layer 120 having a relatively high dielectric constant (hereinafter, referred to as a high-k dielectric layer 120) may be formed on the semiconductor substrate 100. The high-k dielectric layer 120 may have a dielectric constant that is higher than a conventional oxide layer. The high-k dielectric layer 120 may serve as a gate insulation layer in a transistor.

The high-k dielectric layer 120 may, include, for example, a high-k material such as tantalum oxide (Ta₂O₅), titanium oxide (TiO₂), zirconium oxide (ZrO₂), hafnium silicon oxynitride (HfSi_{X}O_{Y}N_{Z}), zirconium silicon oxynitride (ZrSi_{X}O_{Y}N_{Z}), aluminum oxide (Al₂O₃), aluminum oxynitride (Al_{X}O_{Y}N_{Z}), hafnium aluminum oxide (HfAl_{X}O_{Y}), yttrium oxide (Y₂O₃), niobium oxide (Nb₂O₅), cesium oxide (CeO₂), indium oxide (InO₃), lanthanum oxide (LaO₂), BST [(Ba, Sr)TiO₃], PZT [(Pb, Zr)TiO₃], strontium titanium oxide (SrTiO₃), lead titanium oxide (PbTiO₃), strontium ruthenium oxide (SrRuTiO₃), calcium ruthenium oxide (CaRuTiO₃), PLZT [Pb(La, Zr)TiO₃], SCR [(Sr, Ca)RuO₃], etc. The materials may be used alone or in any combination thereof.

Further, the high-k dielectric layer 120 may have a laminate structure in which a plurality of thin films including the high-k material are sequentially stacked on the substrate 100.

A gate electrode 190 may be formed on the high-k dielectric layer 120. A gate spacer 160 is formed on a sidewall of the gate electrode 190.

The gate electrode 190 may include a tantalum carbon nitride layer pattern 135 and a conductive layer pattern 145 sequentially formed on the high-k dielectric layer 120.

The tantalum carbon nitride layer pattern 135 may be formed by method embodiments of the present invention. Thus, the tantalum carbon nitride layer pattern 135 may be formed by introducing a source gas including a tantalum metal complex onto the surface of a high-k dielectric layer 120 and thermally decomposing the tantalum metal complex. The tantalum metal complex may include one or more ligands bound to a tantalum metal, wherein one or more of the ligands include nitrogen and one or more of the ligands include carbon. The tantalum carbon nitride layer pattern 135 may have a low reactivity towards the high-k dielectric layer 120. Additionally, the tantalum carbon nitride layer pattern 135 may have a high work function in a range of about 4.6 eV to about 5.3 eV. Therefore, the tantalum carbon nitride layer pattern 135 may be advantageously employed in the gate electrode 190.

The tantalum carbon nitride layer pattern 135 may include about 5 to about 50 percent by weight of carbon based on the entire weight of the tantalum carbon nitride. In some embodiments, the tantalum carbon nitride layer pattern 135 may have a thickness in a range of about 20 Å to about 2,000 Å, as measured from the upper face of the high-k dielectric layer 120. In some embodiments, the-tantalum carbon nitride layer pattern 135 may have a thickness in a range of about 20 Å to about 300 Å.

The conductive layer pattern 145 may be formed on the tantalum carbon nitride layer pattern 135 so as to form the gate electrode 190 and to maintain the source/drain regions of the transistor. In some embodiments, the conductive layer pattern 145 may include a metal or a metal silicide. For example, in some embodiments, the conductive layer pattern 145 may include tungsten, tantalum, titanium, aluminum, copper, titanium silicide, cobalt silicide, tungsten silicide, tantalum silicide, and the like. The materials can be used alone or in any combination thereof. In other embodiments, the conductive layer pattern 145 may include polysilicon doped with impurities. In some embodiments, the conductive layer pattern 145 may have a thickness in a range of about 1,000 Å to about 3,000 Å, as measured from the upper face of the tantalum carbon nitride layer pattern 135.

First impurity regions 150, which include low concentrations of impurities, are formed at portions of the substrate 100 under the respective lower edge portions of the gate electrode 190. In some embodiments, the first impurity regions 150 may be doped with P-type impurities.

Second impurity regions 170, which include high concentrations of impurities, may be formed at portions of the substrate 100 adjacent to the gate electrode 190. The second impurity regions 170 may make contact with the respective first impurity regions 150. The second impurity regions 170 may be doped with P-type impurities.

Each of the second impurity regions 170 may have an impurity concentration and a depth substantially larger than the impurity concentration and the depth of the first impurity region 150. The first and the second impurity regions 150 and 170 together form lightly doped drain (LDD) structures that may serve as the source/drain regions of the transistor.

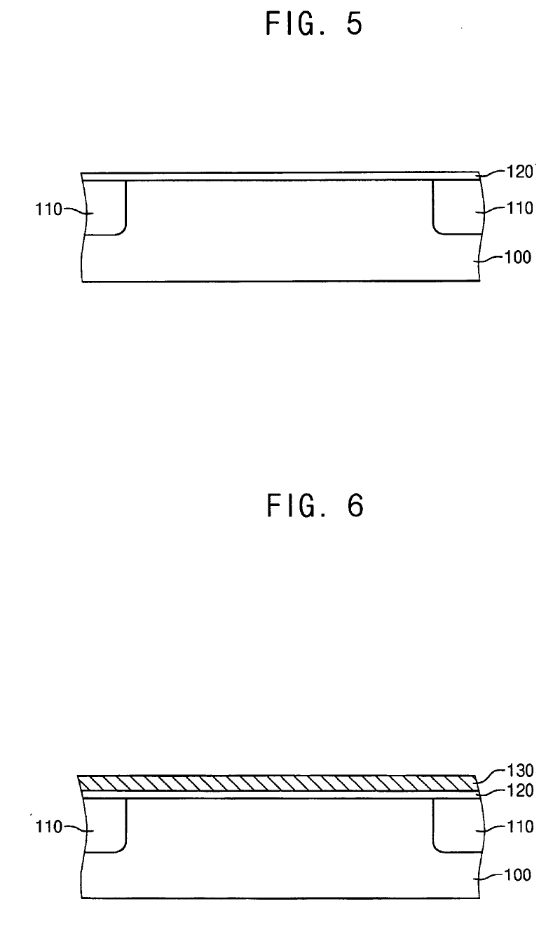

FIGS. 5 to 9 are cross-sectional views illustrating methods of forming a gate structure according to some embodiments of the present invention. In FIGS. 5 to 9, the methods of forming the gate structure may be advantageously employed in the formation of a PMOS transistor.

Referring to FIG. 5, an isolation layer 110 may be formed at an upper portion of a semiconductor substrate 100 to define an active region where the gate structure is positioned. The isolation layer 110 may be formed by an isolation process such as a shallow trench isolation (STI) process.

In some embodiments of the present invention, an inner oxide layer (not shown) and/or a nitride liner (not shown) may be formed between the isolation layer 110 and the upper portion of the semiconductor substrate 100.

A channel region (not shown) may be formed in the active region-by doping impurities into the active region. In some embodiments, the channel region of a transistor may be formed using N-type impurities.

A high-k dielectric layer 120 may be formed on the semiconductor substrate 100. The high-k dielectric layer 120 may serve as the gate insulation layer of the transistor. The high-k dielectric layer 120 may be formed using a high-k dielectric material that has a higher dielectric constant than an oxide layer. The high-k dielectric layer 120 may be formed using, for example, tantalum oxide (Ta₂O₅), titanium oxide (TiO₂), zirconium oxide (ZrO₂), hafnium silicon oxynitride (HfSi_{X}O_{Y}N_{Z}), zirconium silicon oxynitride (ZrSi_{X}O_{Y}N_{Z}), aluminum oxide (Al₂O₃), aluminum oxynitride (Al_{X}O_{Y}N_{Z}), hafnium aluminum oxide (HfAl_{X}O_{Y}), yttrium oxide (Y₂O₃), niobium oxide (Nb₂O₅), cesium oxide (CeO₂), indium oxide (InO₃), lanthanum oxide (LaO₂), BST [(Ba, Sr)TiO₃], PZT [(Pb, Zr)TiO₃], strontium titanium oxide (SrTiO₃), lead titanium oxide (PbTiO₃), strontium ruthenium oxide (SrRuTiO₃), calcium ruthenium oxide (CaRuTiO₃), PLZT [Pb(La, Zr)TiO₃], SCR [(Sr, Ca)RuO₃], and the like. The materials can be used alone or in any combination thereof.

In some embodiments of the present invention, the high-k dielectric layer 120 may have a laminate structure in which a plurality of films including metal oxide are alternatively or sequentially formed on the substrate 100.

In some embodiments of the present invention, the high-k dielectric layer 120 may be formed by a CVD process, an ALD process, or a metal organic chemical vapor deposition (MOCVD) process. Other suitable processes may also be used to form the high-k dielectric layer.

Since the high-k material in the high-k dielectric layer 120 may exhibit strong ion polarization, the high-k dielectric layer 120 may have a relatively high dielectric constant. To maximize the dielectric constant, the high-k dielectric material may have a precise stoichiometry and a crystalline structure without impurities therein. When a high-k dielectric layer 120 is formed at a temperature in a range of about 400° C. to about 700° C. by a MOCVD process, the above-mentioned conditions necessary for maximizing the dielectric constant of the high-k dielectric material may not be present. Therefore, the high-k dielectric layer 120 may be thermally treated in order to achieve suitable storage capacitance and minimize the leakage current when the high-k dielectric layer 120 is formed at such temperatures.

This thermal post-treatment of the high-k dielectric layer 120 may remove impurities from the high-k dielectric layer 120 formed on the substrate 100. For example, methane and water vapor may be removed from the high-k dielectric layer 120 when the thermal post-treatment is carried out at a temperature of about 600° C. In some embodiments of the present invention, carbon dioxide generated from metal carbonate impurities in the high-k dielectric layer 120 may be removed from the high-k dielectric layer 120 through thermal post-treatment performed at a temperature of about 900° C. when the high-k dielectric layer 120 is formed using BST. The removal of impurities from the high-k dielectric layer 120 may be identified by thermal desorption spectroscopy. When impurities are removed from the high-k dielectric layer 120, the high-k dielectric layer 120 may have an increased density, which may enhance capacitance and reduce the leakage current.

When thermal post-treatment is performed on the high-k dielectric layer 120, the resultant high-k dielectric material in the high-k dielectric layer 120 may have a stoichiometry that provides the dielectric layer with excellent electrical characteristics. For example, when the high-k dielectric layer 120 is formed using tantalum oxide, the high-k dielectric layer 120 may not have the desired content of oxygen. However, after the high-k dielectric layer 120 is thermally treated under an oxygen atmosphere, the high-k dielectric layer 120 may have a stoichiometry with a more desirable amount of oxide.

After the thermal post-treatment process is carrier out on the high-k dielectric layer 120, the high-k material in the high-k dielectric layer 120 may be crystallized. When a high-k dielectric layer 120 is formed at a relatively low temperature, the high-k material in the high-k dielectric layer 120 may have an amorphous structure so that the high-k dielectric layer 120 may not have desirable electrical characteristics. However, after thermal post-treatment, the high-k dielectric layer 120 may have a desirable microcrystalline structure. In some embodiments, a high-k dielectric layer 120 including tantalum oxide may be thermally treated at a temperature of about 800° C. In some embodiments, a high-k dielectric layer 120 of BST may be thermally treated at a temperature of about 700° C.

When thermal post-treatment is performed on the high-k dielectric layer 120 for an excessively long time, oxygen in the high-k dielectric layer 120 may react with the silicon in the substrate 100. Thus, an undesired silicon oxide layer may be formed between the substrate 100 and the high-k dielectric layer 120. When an undesired silicon oxide layer is formed between the substrate 100 and the high-k dielectric layer 120, the undesired silicon oxide layer may reduce the capacitance of the high-k dielectric layer 120. Therefore, in some embodiments, the thermal post-treatment may be limited to a time period such that the undesired silicon oxide layer is not formed.

Referring to FIG. 6, a source gas including a tantalum metal complex is provided onto the high-k dielectric layer 120, and then the tantalum metal complex is thermally decomposed to form a tantalum carbon nitride layer 130 on the high-k dielectric layer 120. The tantalum metal complex may include one or more ligands bound to a tantalum metal, wherein one or more of the ligands include nitrogen and one or more of the ligands include carbon. The tantalum carbon nitride layer 130 may serve as a gate electrode of a transistor.

When the gate electrode of polysilicon contacts the high-k dielectric layer 120 directly, the gate electrode may react with the high-k dielectric layer 120, thereby causing a Fermi-level pinning effect. When the Fermi-level pinning effect is generated between the gate electrode and the high-k dielectric layer 120, the transistor including the polysilicon gate electrode may have an undesirably high threshold voltage. Therefore, the gate electrode of the transistor may include a metal so as to prevent the Fermi-level pinning effect because the metal gate electrode may not react with the high-k dielectric material 120. Additionally, the gate electrode may have excellent oxidation resistance, which may prevent oxidation of the gate electrode resulting in an increase in the equivalent oxide thickness (EOT) of the gate electrode. Furthermore, in some embodiments, the gate electrode may advantageously have a high work function in a range of about 4.6 eV to about 5.2 eV when the gate electrode is employed in a PMOS transistor.

The tantalum carbon nitride layer 130 formed according to a method embodiment of the present invention may sufficiently meet the above-mentioned conditions for the gate electrode. To obtain the tantalum carbon nitride layer 130, a transition metal complex represented by the following chemical formula may be used:
Ta(NR₁)(NR₂R₃)₃

In the above chemical formula, R₁, R₂ and R₃ may each independently be either H or a C₁-C₆ alkyl. For example, in some embodiments, a source gas including TAIMATA® is used to form the tantalum carbon nitride layer 130 on the high-k dielectric layer 120.

In the formation of the tantalum carbon nitride layer 130, according to some embodiments of the present invention, a carrier gas may be introduced together with the source gas including TAIMATA®. The TAIMATA® may have a liquid phase at room temperature and so may be vaporized by bubbling with the carrier gas. The vapor phase of TAIMATA® may then be provided onto the high-k dielectric layer 120. The carrier gas may include, for example, an inert gas such as argon, helium, nitrogen, and the like.

During the formation of the tantalum carbon nitride layer 130 on the substrate 100, a pressure control gas may be additionally provided to the chamber wherein the substrate 100 having the high-k dielectric layer 120 thereon is loaded. The pressure control gas may adjust the internal pressure of the chamber. The pressure control gas may include, for example, an inert gas such as argon, helium, nitrogen, and the like. In some embodiments, the carrier gas may be substantially the same as the pressure control gas. However, in some embodiments, the pressure control gas may be different from the carrier gas.

During the thermal decomposition of the tantalum metal complex, the chamber wherein the tantalum carbon nitride layer 130 is formed may have a temperature in a range of about 400° C. to about 700° C. and a pressure in a range of about 0.01 Torr to about 100 Torr.

The tantalum carbon nitride layer 130 formed by a method according to some embodiments of the present invention may have a work function in a range of about 4.6 eV to about 5.2 eV, so that the tantalum carbon nitride layer 130 formed may be advantageously used as the gate electrode of the PMOS transistor. In some embodiments, the tantalum carbon nitride layer 130 may include about 5 to about 50 percent by weight of carbon based on the total weight of the tantalum carbon nitride.

To adjust the content of nitrogen in the tantalum carbon nitride layer 130, a first reaction gas including nitrogen may be introduced into the chamber while forming the tantalum carbon nitride layer 130. The first reaction gas may include, for example, nitrogen, NH₃, N₂H₂ and the like. The gases can be used alone or in any combination thereof.

A second reaction gas including carbon may be provided onto the high-k dielectric layer 120 while forming the tantalum carbon nitride layer 130 so as to adjust the content of carbon in the tantalum carbon nitride layer 130. The second reaction gas may include, for example, CH₄ or C₂H₂. The gases can be used alone or in any combination thereof.

The work function of the tantalum carbon nitride layer 130 may vary according to the content of nitrogen and carbon in the tantalum carbon nitride layer 130.

Since metals generally have a specific Fermi-level, the Fermi-level of the metal is not changed by doping impurities into the metal. Hence, the gate electrode may have a fixed work function when the gate electrode includes only a metal. However, a transistor may require a metal having a specific work function to obtain the desired threshold voltage because the threshold voltage of the transistor may depend mostly on the work function of the gate electrode of the transistor. When the NMOS transistor has a threshold voltage in a range of about 0.3V to about 0.9V, the gate electrode of the NMOS transistor may include a conductive material having a work function in a range of about 3.7 eV to about 4.2 eV. On the contrary, a gate electrode of a PMOS transistor may include a conductive material having a work function of about 5.2 eV when the PMOS transistor has a threshold voltage in a range of about −0.3V to about −0.9V. However, a novel metal compound having a high work function is desirable for the PMOS transistor because conventional metals may not have desirable work functions for PMOS transistors.

A tantalum carbon nitride layer 130, according to some embodiments of the present invention, has a work function in a range of about 4.6 eV to about 5.2 eV, so that the tantalum carbon nitride layer 130 may advantageously make the threshold voltage of a PMOS transistor in a range of about −0.3V to about −0.9V.

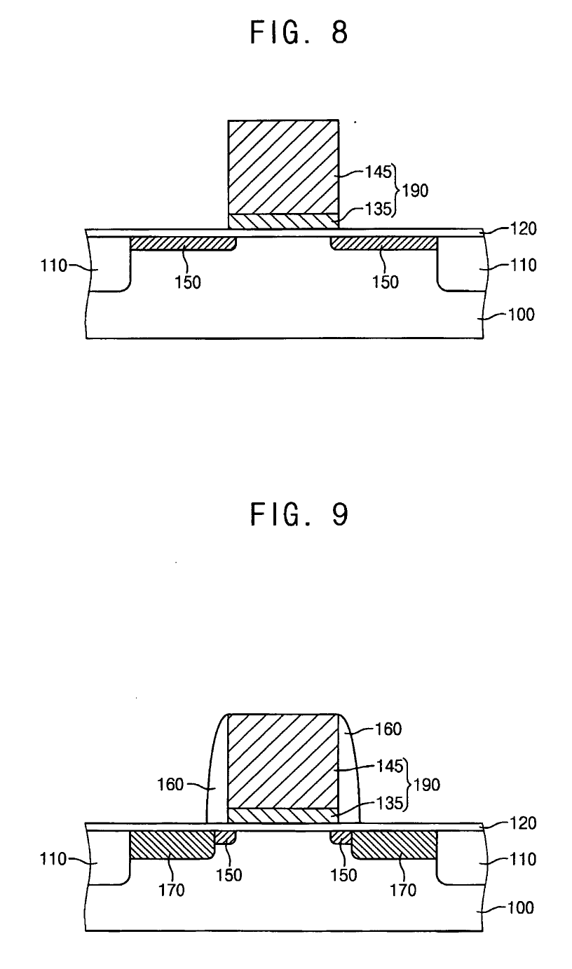

The high-k dielectric layer 120 may include the high-k material having an etching selectivity relative to the tantalum carbon nitride layer 130, in consideration of a later etching process for forming a gate electrode 190 (see FIG. 8).

The tantalum carbon nitride layer 130 may not be easily etched by a dry etching process. Particularly, the tantalum carbon nitride layer 130 may be hardly etched by an etching process when the tantalum carbon nitride layer 130 is relatively thick. Further, the tantalum carbon nitride layer 130 may have a high specific resistance because the tantalum carbon nitride layer 130 includes carbon. Therefore, to reduce the specific resistance of the tantalum carbon nitride layer 130 and to readily form the gate electrode 190, the tantalum carbon nitride layer 130 may be advantageously formed so as to be as thin as possible, while still thick enough to effectively serve as the gate electrode and to sufficiently endure successive thermal processes. In some embodiments of the present invention, the tantalum carbon nitride layer 130 may have a thickness in a range of about 20 Å to about 1,000 Å. In some embodiments, the tantalum carbon nitride layer 130 may have a thickness in a range of about 20 Å to about 300 Å.

In some embodiments of the present invention, the tantalum carbon nitride layer 130 may be treated after the formation of the tantalum carbon nitride layer 130. In some embodiments, the tantalum carbon nitride layer 130 may be treated using NH₃, H₂, N₂, SiH₄ or Si₂H₆ activated through a remote plasma process or a direct plasma process. However, the post-treatment process may be omitted, thus simplifying the manufacturing process of the gate electrode 190.

In some embodiments of the present invention, the tantalum carbon nitride layer 130 may be doped with nitrogen atoms or oxygen atoms so as to improve the electrical characteristics of the tantalum carbon nitride layer 130 and simultaneously adjust the work function of the tantalum carbon nitride layer 130.

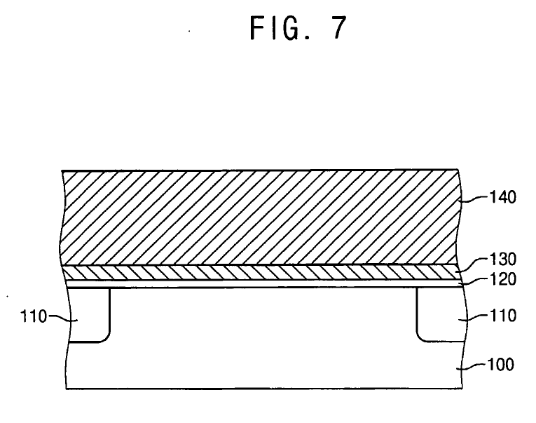

Referring to FIG. 7, a conductive layer 140 may be formed on the tantalum carbon nitride layer 130. Since the tantalum carbon nitride layer 130, in some embodiments, has a thickness in a range of about 20 Å to about 1,000 Å, as described above, a gate electrode 190 may not be formed on the substrate 100 by an etching process when the gate electrode 190 includes the tantalum carbon nitride layer 130 only. Additionally, source/drain regions may not be properly formed when the source/drain regions are formed by ion implantation processes using the gate electrode 190 including the tantalum carbon nitride layer 130 only. Therefore, the conductive layer 140 may be advantageously formed on the tantalum carbon nitride layer 130.

In some embodiments, the conductive layer 140 may be formed using polysilicon doped with impurities. In other embodiments, the conductive layer 140 may be formed using a metal or a metal silicide. For example, the conductive layer 140 may be formed using tantalum (Ta), titanium (Ti), aluminum (Al), copper, titanium silicide (TiSi_{X}), cobalt silicide (CoSi_{X}), tungsten silicide (WSi_{X}), tantalum silicice (TaSi_{X}), and the like. The materials can be used alone or in any combination thereof.

The conductive layer 140 may have a sufficient thickness so as to ensure a process margin during the etching process for forming the gate electrode 190. In some embodiments of the present invention, the conductive layer 140 may have a thickness of above about 1,000 Å. For example, in some embodiments, the conductive layer 140 may have a thickness in a range of about 1,000 Å to about 3,000 Å. In some embodiments, the conductive layer 140 may be formed by a PVD process or a CVD process.

Referring to FIG. 8, the conductive layer 140 and the tantalum carbon nitride layer 130 may be sequentially etched to thereby form a tantalum carbon nitride layer pattern 135 and a conductive layer pattern 145 on the substrate 100. Thus, the gate electrode 190 may be formed on the substrate 100. In some embodiments, the gate electrode 190 may extend to cross the isolation layer 110 while exposing the high-k dielectric layer 120. In some embodiments, the gate electrode 190 may be formed by an anisotropic etching process.

In some embodiments of the present invention, a portion of the high-k dielectric layer 120 adjacent to the gate electrode 190 may serve as a buffer layer that prevents channeling of ions during the ion implantation process for forming the source/drain regions.

The etching process for forming the gate electrode 190 may be carried out without damage to the portions of the substrate 100 where the source/drain regions are formed. Thus, in some embodiments, the gate electrode 190 may be formed using an etching solution or an etching gas that has an etching selectivity between the high-k dielectric layer 120 and the gate electrode 190.

Using the gate electrode 190 as an implantation mask, impurities may be implanted into first portions of the substrate 100 adjacent to the gate electrode 190, thereby forming first impurity regions 150 wherein the substrate 100 has low concentrations of impurities. In some embodiments, the first impurity regions 150 may be formed using P-type impurities.

Referring to FIG. 9, a gate spacer 160 may be formed on a sidewall of the gate electrode 190, and impurities may be implanted into second portions of the substrate 100 wherein the first impurity regions 150 are positioned using the gate spacer 160 and the gate electrode 190 as implantation masks. Hence, second impurity regions 170 having relatively high impurity concentrations are formed on the second portions of the substrate 100. In some embodiments, the second impurity regions 170 may be formed using P-type impurities.

In some embodiments of the present invention, a thermal treatment process may be performed on the substrate 100 after the formation of the second impurity regions 170 in order to activate the implanted impurities. In some embodiments, the thermal treatment process may include a rapid thermal process (RTP).

After the second impurity regions 170 are formed, a PMOS transistor is formed on the substrate 100. The PMOS transistor includes the gate electrode 190 and the source/drain regions composed of the first and the second impurity regions 150 and 170. Since the PMOS transistor includes the gate structure having a tantalum carbon nitride layer pattern 135, the Fermi-level pinning phenomenon may not occur in the PMOS transistor when the PMOS transistor includes the high-k dielectric layer 120. Further, the PMOS transistor may have a threshold voltage in a range of about −0.5V to about −0.9V because the tantalum carbon nitride layer pattern 135 may have a work function in a range of about 4.6 eV to about 5.2 eV.

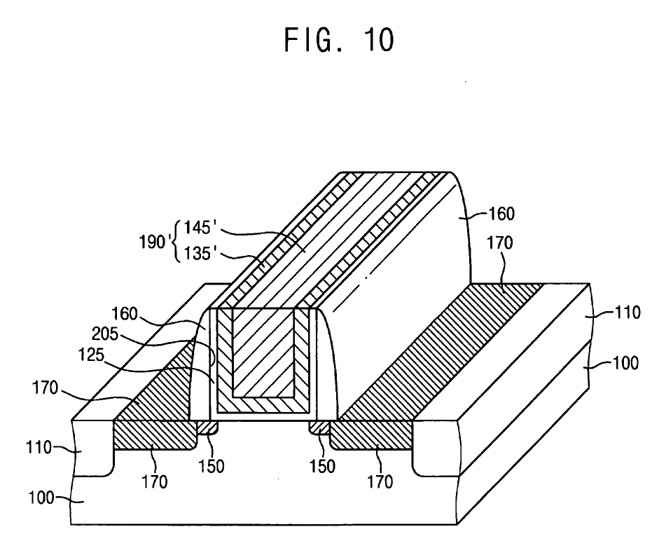

FIG. 10 is a perspective view illustrating a gate structure according to some embodiments of the present invention. As shown in FIG. 10, in some embodiments, the gate structure may be formed through a damascene process. The gate structure of FIG. 10 may have a construction substantially similar to that of the gate structure of FIG. 4. Referring to FIG. 10, an isolation layer 110 may be formed on an upper portion of a semiconductor substrate 100 to define an active region. A channel doping region (not shown) serving as a channel region of the transistor may be formed in the active region. In some embodiments, the channel doping region may be doped with N-type impurities.

A gate electrode 190′ may be formed on the active region to cross the isolation layer 110. A gate spacer 160 may be formed on the sidewall of the gate electrode 190′.

The gate electrode 190′ may include a tantalum carbon nitride layer pattern 135′ and a conductive layer pattern 145′.

The tantalum carbon nitride layer pattern 135′ may have a thickness in a range of about 20 to about 2,000 Å. In some embodiments, the tantalum carbon nitride layer pattern 135′ may have a U shape that encloses the conductive layer pattern 145′. Particularly, the tantalum carbon nitride layer pattern 135′ may enclose a bottom and a sidewall of the conductive layer 145′. The tantalum carbon nitride layer pattern 135′ may be formed by a process substantially the same as that described with reference to FIGS. 6 to 8.

The conductive layer pattern 145′ may be formed on the tantalum carbon nitride layer pattern 135′ in order to form the gate electrode 190′ and maintain the source/drain regions of the transistor. In some embodiments, the conductive layer pattern 145′ may include a metal or a metal silicide such as tungsten, tantalum, titanium, aluminum, copper, titanium silicide, cobalt silicide, tungsten silicide, tantalum silicide, and the like. The materials can be used alone or in any combination thereof. In some embodiments, the conductive layer pattern 145′ may include polysilicon doped with impurities.

A high-k dielectric layer pattern 125 may be formed on the sidewall of the gate electrode 190′ and beneath a bottom of the gate electrode 190′. In particular, the high-k dielectric layer pattern 125 may be formed between the sidewall of the gate electrode 190′ and the gate spacer 160 and between the bottom of the gate electrode 190′ and the semiconductor substrate 100. That is, the high-k dielectric layer pattern 125 may enclose the gate electrode 190′. When the tantalum carbon nitride layer pattern 135′ has the U shape, the high-k dielectric layer pattern 125 may also have a U shape.

The high-k dielectric layer pattern 125 may serve as the gate insulation layer of the transistor. The high-k dielectric layer pattern 125 may include, for example, a high-k material such as tantalum oxide, titanium oxide, zirconium oxide, hafnium silicon oxynitride, zirconium silicon oxynitride, aluminum oxide, aluminum oxynitride, hafnium aluminum oxide, yttrium oxide, niobium oxide, cesium oxide, indium oxide, lanthanum oxide, BST, PZT, strontium titanium oxide, lead titanium oxide, strontium ruthenium oxide, calcium ruthenium oxide, PLZT, SCR, and the like. The materials can be used alone or in any combination thereof. The high-k dielectric layer pattern 125 may have a laminate structure in which a plurality of thin films including a high-k material are sequentially stacked.

First impurity regions 150 having low impurity concentrations may be formed at first portions of the substrate 100 under respective lower edge portions of the gate electrode 190′. In some embodiments, the first impurity regions 150 may be doped with P-type impurities. Second impurity regions 170 having high impurity concentrations may be formed at second portions of the substrate 100 adjacent to the gate electrode 190′. The second impurity regions 170 may make contact with the respective first impurity regions 150. In some embodiments, the second impurity regions 170 may be doped with P-type impurities.

Each of the second impurity regions 170 may have an impurity concentration and depth greater than the impurity concentration and depth of the first impurity regions 150. The first and the second impurity regions 150 and 170 together may form LDD structures that serve as the source/drain regions of the transistor.

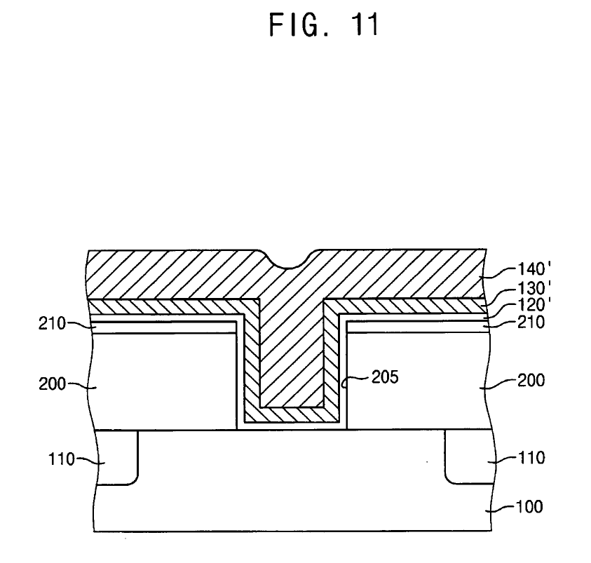

FIGS. 11 to 13 are cross-sectional views illustrating methods of forming gate structures according to some embodiments of the present invention. Referring to FIG. 11, an isolation layer 110 may be formed at an upper portion of a semiconductor substrate 100 to define an active region on which the gate structure may be formed.

A mold layer may be formed on the semiconductor substrate 100 that includes isolation layer 110, and the mold layer may be partially etched to form a mold layer pattern 200 on the semiconductor substrate 100. The mold layer pattern 200 may cross the isolation layer 110. The mold layer pattern 200 may have an opening 205 that exposes a portion of the semiconductor substrate 100. In some embodiments, the mold layer pattern 200 may be employed in the formation of the gate structure by a damascene process.

In some embodiments of the present invention, the mold layer pattern 200 may be formed through an anisotropic etching process using an etching solution or an etching gas that has an etching selectivity between the mold layer and the semiconductor substrate 100. Thus, the mold layer may be formed using a material having an etching selectivity relative to the semiconductor substrate 100. Further, the material of the mold layer may have an etching selectivity with respect to the high-k dielectric layer 120′, the tantalum carbon nitride layer 130′ and the conductive layer 140′ in order to prevent damage to the gate electrode in an etching process for removing the mold layer pattern 200 after the formation of the gate structure. For example, the mold layer may be formed with silicon oxide, silicon nitride or silicon oxynitride.

An anti-reflective layer 210 may be formed on the mold layer so as to ensure a process margin in a photolithography process for forming the mold layer pattern 200. In some embodiments, the anti-reflective layer 210 may be formed using silicon oxynitride. In some embodiments, for example, when the mold layer includes silicon oxynitride, the anti-reflective layer 210 may be omitted.

In some embodiments, a high-k dielectric layer 120′ may be continuously formed on the exposed portion of the semiconductor substrate 100, the sidewall of the mold layer pattern 200 and on the anti-reflective layer 210. The high-k dielectric layer 120′ may be formed by a process substantially the same as that described with reference to FIG. 5.

The tantalum carbon nitride layer 130′ may be formed on the high-k dielectric layer 120′ using a source gas that includes a tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom. The tantalum metal complex may be thermally decomposed to form a tantalum carbon nitride layer 130′ on the high-k dielectric layer 120′.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. The term C₁-C₆ alkyl, as used herein, is meant to refer to any alkyl having from 1 to 6 carbon atoms. In some embodiments, the tantalum metal complex is TAIMATA®.

In some embodiments of the present invention, a carrier gas and/or a pressure control gas may be introduced into the process chamber where the tantalum carbon nitride layer 130′ is formed. The carrier gas may provide the source gas onto the semiconductor substrate 100 including the high-k dielectric layer 120′. The pressure control gas may adjust the internal pressure of the process chamber during the formation of the tantalum carbon nitride layer 130′. In some embodiments, the carrier gas and the pressure control gas may be provided into the process chamber through different gas supply lines. The carrier and the pressure control gases may include inert gases such as argon, nitrogen, helium and the like.

The conductive layer 140′ may be formed on the tantalum carbon nitride layer 130′ to sufficiently fill up the opening 205 of the mold layer pattern 200. In some embodiments, the conductive layer 140′ may be formed using a metal or a metal silicide such as tungsten, tantalum, titanium, aluminum, copper, titanium silicide, cobalt silicide, tungsten silicide, tantalum silicide and the like. The materials can be used alone or in any combination thereof. In some embodiments, the conductive layer 140′ may be formed using polysilicon doped with impurities.

When the gate structure is formed through a damascene process, the conductive layer 140′ may be advantageously formed using copper so as to reduce the resistance of the gate structure. A conductive layer 140′ that includes copper may be formed by an electroplating process.

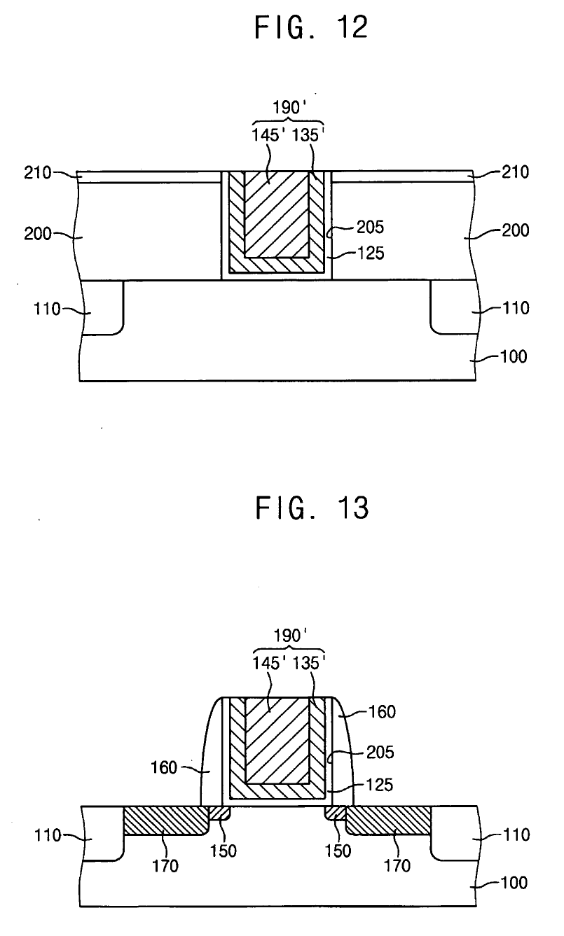

Referring to FIG. 12, the conductive layer 140′, the tantalum carbon nitride layer 130′ and the high-k dielectric layer 120′ may be partially removed until the anti-reflective layer 210 is exposed. In some embodiments, the conductive layer 140′, the tantalum carbon nitride layer 130′ and the high-k dielectric layer 120′ may be partially removed by a chemical mechanical polishing (CMP) process. Thus, a high-k dielectric layer pattern 125, a tantalum carbon nitride layer pattern 135′ and a conductive layer pattern 145′ may be.formed in the opening 205. As shown in FIG. 12, in some embodiments, cross-sections of the high-k dielectric layer pattern 125 and tantalum carbon nitride layer pattern 135′ may have U shapes whereas a cross-section of the conductive layer pattern 145′ may have a rectangular shape.

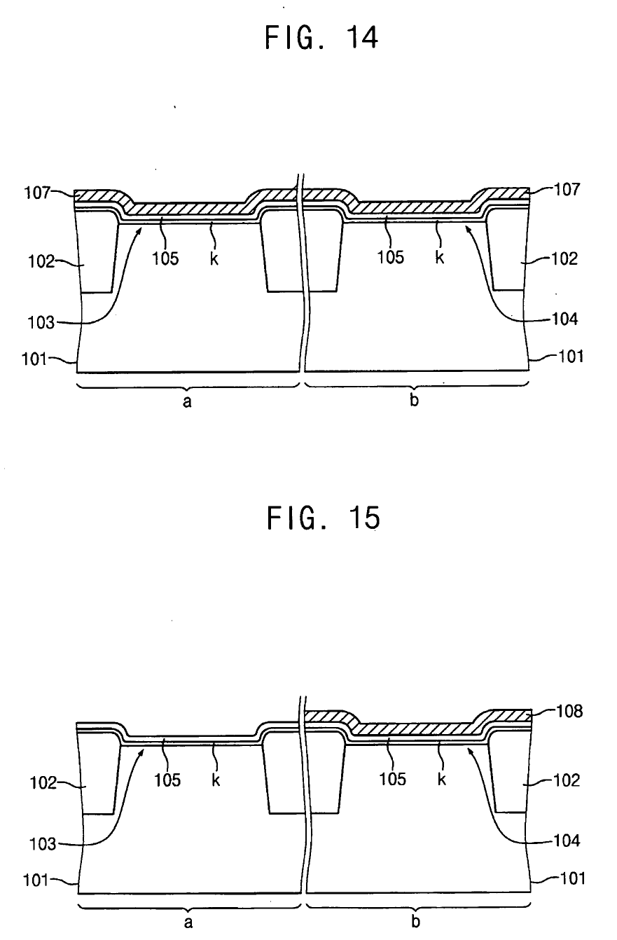

Referring to FIG. 13, the anti-reflective layer 210 and the mold layer pattern 200 may be removed to expose portions of the semiconductor substrate 100 adjacent to the gate electrode 190′. In some embodiments, the anti-reflective layer 210 and the mold layer pattern 200 may be removed by an isotropic etching process. In an isotropic etching process, the anti-reflective layer 210 and the mold layer pattern 200 may be removed using an etching gas or an etching solution that has an etching selectivity with respect to the semiconductor substrate 100, the high-k dielectric layer pattern 125, the tantalum carbon nitride layer pattern 135′ and the conductive layer pattern 145′.

First impurities may be implanted into the exposed portions of the semiconductor substrate 100 adjacent to the gate electrode 190′ by an ion implantation process using the gate electrode 190′ as an implantation mask. Hence, first impurity regions 150 may be formed adjacent to the gate electrode 190′. The first impurity regions 150 may be formed using P-type impurities. Each of the first impurity regions 150 may have a low impurity concentration.

A gate spacer 160 may be formed on a sidewall of the gate electrode 190′, second impurities may be implanted into the exposed portions of the semiconductor substrate 100 adjacent to the first impurity regions 150 by an ion implantation process using the gate electrode 190′ and the gate spacer 160 as implantation masks. Thus, second impurity regions 170 may be formed adjacent to the respective first impurity regions 150. The second impurity regions 170 may be formed using P-type impurities. Each of the second impurity regions 170 may have a high impurity concentration.

In some embodiments of the present invention, a thermal treatment process may be performed on the semiconductor substrate 100 to activate the first and the second impurities in the first and the second impurity regions 150 and 170, respectively.

In some embodiments of the present invention, a buffer layer may be formed on the exposed portions of the semiconductor substrate 100 adjacent to the gate electrode 190′ so as to prevent ion channeling and/or damage to the semiconductor substrate 100 generated in the ion implantation processes when the first and the second impurities are directly implanted into the exposed portions of the semiconductor substrate 100.

Further, in some embodiments of the present invention, the first and the second impurities may be implanted to form first and second impurity regions 150 and 170 by slant ion implantation processes to reduce the ion channeling and/or the damage to the semiconductor substrate 100.

In some example embodiments of the present invention, the gate electrode 190′ may include the tantalum carbon nitride layer pattern 135′ formed on the high-dielectric layer pattern 125 without the formation of the conductive layer pattern 145′. Here, the tantalum carbon nitride layer pattern 135′ may be formed by a damascene process. A tantalum carbon nitride layer pattern may be formed with a sufficient thickness to fill up the opening 205 of the mold layer pattern 200 through a process substantially the same as that described with reference to FIG. 6, and the tantalum carbon nitride layer may be partially removed by a CMP process until the anti-reflective layer 210 is exposed. Thus, the tantalum carbon nitride layer pattern 135′ may be formed on-the high-k dielectric layer pattern 125 to fill up the opening 205. When the tantalum carbon nitride layer pattern 135′ is formed through a damascene process, the tantalum carbon nitride layer pattern 135′ may have a sufficient thickness because no photolithography process is used to form the tantalum carbon nitride layer pattern 135′. Although a gate electrode 190′ including only the tantalum carbon nitride layer pattern 135′ may have a relatively high specific resistance, the manufacturing process for the gate structure may be simplified because the conductive layer pattern 145′ is omitted.

In some embodiments, to reduce the specific resistance of the gate structure, an additional conductive layer pattern may be formed on the tantalum carbon nitride layer pattern 135′ before the mold layer pattern 200 is removed. Here, the gate electrode 190′ may include the tantalum carbon nitride layer pattern 135′, an additional conductive layer pattern and the conductive layer pattern 145′.

Method of Forming Dual Gate Structures in a Semiconductor Device

FIGS. 14 to 18 are cross-sectional views illustrating methods of manufacturing dual gate structures in a semiconductor device according to some embodiments of the present invention. In FIGS. 14 to 18, “a” indicates an NMOS transistor area of a semiconductor substrate 101 and “b” represents a PMOS transistor area of the semiconductor substrate 101.

Referring to FIG. 14, an isolation layer 102 may be formed on the semiconductor substrate 101 to define active regions and field regions of the semiconductor substrate 101.

P-type impurities may be doped in a first active region of the NMOS transistor area to form a first channel region 103, whereas N-type impurities are doped in a second active region of the PMOS transistor area to form a second channel region 104.

In some embodiments of the present invention, the P-type impurities and the N-type impurities may be implanted into the first active region and the second active region, respectively.

In some embodiments of the present invention, after the isolation layer 102 is formed on the semiconductor substrate 101 including P-type impurities to define the first and the second active regions, the N-type impurities may be selectively doped in the second active region of the PMOS transistor area to form the second channel region 104 from the first channel region 103 that was previously formed.

A high-k dielectric layer 105 may be formed on the isolation layer 102 and the semiconductor substrate 101 having the NMOS area “a” and the PMOS area “b”. The high-k dielectric layer 105 may serve as a gate insulation layer. In some embodiments, the high-k dielectric layer 105 may be formed using a dielectric material that has a dielectric constant higher than that of silicon oxide. For example, the high-k dielectric layer 105 may be formed using tantalum oxide, titanium oxide, zirconium oxide, hafnium silicon oxynitride, zirconium silicon oxynitride, aluminum oxide, aluminum oxynitride, hafnium aluminum oxide, yttrium oxide, niobium oxide, cesium oxide, indium oxide, lanthanum oxide, BST, PZT, strontium titanium oxide, lead titanium oxide, strontium ruthenium oxide, calcium ruthenium oxide, PLZT, SCR, and the like. The materials can be used alone or in any combination thereof.

In some embodiments of the present invention, the high-k dielectric layer 105 may have a laminate structure in which a plurality of films including the above dielectric material are alternately or sequentially formed on the isolation layer 102 and the semiconductor substrate 101.

When the high-k dielectric layer 105 directly contacts the semiconductor substrate 101, a thick silicate layer may be formed between the semiconductor substrate 101 and the high-k dielectric layer 105 due to a reaction between silicon in the semiconductor substrate 101 and oxygen in the high-k dielectric material 105. Therefore, a thin silicate film (k) may be advantageously formed between the semiconductor substrate 101 and the high-k dielectric layer 105 to avoid the formation of the thick silicate layer. The thin silicate film (k) may be formed on the semiconductor substrate 101 and the isolation layer 102.

When the high-k dielectric layer 105 is formed using hafnium oxide, the thin silicate film k may include hafnium silicon oxide. Here, the thin silicate film (k) may have a thickness less than that of a hafnium silicon oxide layer formed by a reaction between the hafnium in the high-k dielectric layer 105 and silicon in the semiconductor substrate 101. Particularly, the thin silicate film (k) may be formed in advance on the semiconductor substrate 101 to have the thickness less than that of a hafnium silicon oxide layer formed during a successive thermal process. Therefore, the thin silicate film (k) between the semiconductor substrate 101 and the high-k dielectric layer 105 may have a desirable thickness since the formation of a relatively thick silicate layer may be prevented despite the performance of successive thermal processes.

A tantalum carbon nitride layer 107 may be formed on the high-k dielectric layer 105. The tantalum carbon nitride layer 107 may be formed by providing a source gas that includes a tantalum metal complex onto the high-k dielectric layer 105 and then thermally decomposing the tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex may be TAIMATA®.

In some embodiments of the present invention, a carrier gas and a pressure control gas may be provided in the formation of the tantalum carbon nitride layer 107. The carrier gas may introduce the source gas onto the semiconductor substrate 101 having the high-k dielectric layer 105 thereon. The pressure control gas may adjust the internal pressure of the process chamber wherein the semiconductor substrate 101 is loaded during forming the tantalum carbon nitride layer 107. In some embodiments, the carrier gas and the pressure control gas may be supplied through different gas supply lines. Each of the carrier gas and the pressure control gas may include an inert gas such as argon, helium, nitrogen and the like.

The tantalum carbon nitride layer 107 may be relatively thin so as to readily form a tantalum carbon nitride layer pattern by an etching process. For example, in some embodiments, the tantalum carbon nitride layer 107 may have a thickness in a range of about 30 Å to about 1,000 Å.

The method of forming the tantalum carbon nitride layer 107 may be substantially the same as that described with reference to FIG. 6. In some embodiments, the tantalum carbon nitride layer 107 may have a work function in a range of about 3.7 eV to about 4.2 eV so that the tantalum carbon nitride layer 107 may be advantageously employed in a gate electrode.

Referring to FIG. 15, a photoresist pattern (not shown) may be formed on the tantalum carbon nitride layer 107 to selectively expose the NMOS transistor area (a).

Using the photoresist pattern as an etching mask, a portion of the tantalum carbon nitride layer 107 in the NMOS transistor area may be selectively removed, thereby forming a first preliminary gate electrode layer pattern 108 that may serve as the gate electrode of the PMOS transistor.

The photoresist pattern may be removed from the tantalum carbon nitride layer 107, for example, by an ashing process and/or a stripping process.

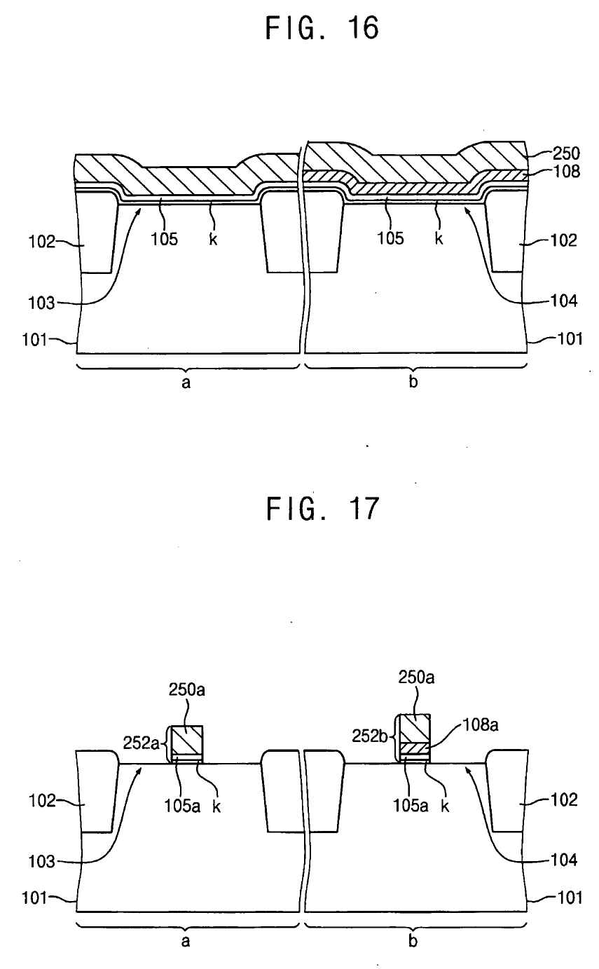

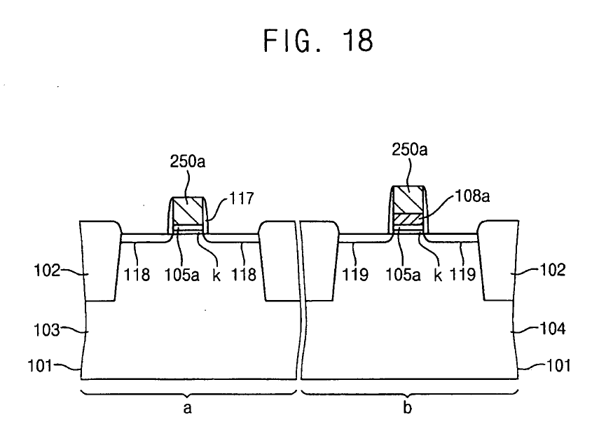

Referring to FIG. 16, a second preliminary gate electrode layer 250 may be formed on the first preliminary gate electrode layer pattern 108. The second preliminary gate electrode layer 250 may serve as a gate electrode of the NMOS transistor.

In some embodiments, to form the gate electrode of the NMOS transistor, the second preliminary gate electrode layer 250 may be formed using a conductive material that has a work function in a range of about 3.8 eV to about 4.4 eV. In some embodiments, the second preliminary gate electrode layer 250 may be formed using a metal compound or a metal. For example, the second preliminary gate electrode layer 250 may be formed using tantalum carbide (TaC), tantalum silicon nitride (TaSiN), tantalum and the like. The materials can be used alone or in any combination thereof. In other embodiments of the present invention, the second preliminary gate electrode layer 250 may be formed using polysilicon doped with N-type impurities.

Although Fermi level pinning effect may occur when a layer of polysilicon doped with N-type impurities is formed on the high-k dielectric layer 105, the degree of the Fermi level pinning effect may be relatively small compared to that of a layer of polysilicon doped with P-type impurities. Thus, the threshold voltage of the NMOS transistor may not be undesirably increased. As a result, in some embodiments, the NMOS transistor may have a threshold voltage in a range of about 0.3V to about 0.9V when the NMOS transistor includes a gate electrode of polysilicon doped with N-type impurities through a channel doping process.

In some embodiments of the present invention, an additional conductive layer may be formed on the second preliminary gate electrode 250 to reduce the resistance of the gate structure. In some embodiments, the additional conductive layer may be formed using a metal or a metal silicide. For example, the additional conductive layer may be formed using tungsten, tantalum, titanium, aluminum, copper, titanium silicide, cobalt silicide, tungsten silicide, tantalum silicide and the like. The materials may be used alone or in combination thereof.

Referring to FIG. 17, the first preliminary gate electrode layer pattern 108 and the second preliminary gate electrode layer 250 may be sequentially patterned. When a silicate layer k is provided with the high-k dielectric layer 105, the silicate layer k may be partially etched together with the high-k dielectric layer 105, the first preliminary gate electrode layer pattern 108 and the second preliminary gate electrode layer 250. Hence, a second gate electrode layer pattern 250a may be formed on the first channel region 103, and also a first gate electrode layer pattern 108a and a second gate electrode layer pattern 250a may be sequentially formed on is the second channel region 104.

In some embodiments, the gate electrode of the NMOS transistor includes a conductive material having a work function in a range of about 3.8 eV to about 4.4 eV. Additionally, in some embodiments, the gate electrode of the PMOS transistor may include tantalum carbon nitride with a work function in a range of about 4.6 eV to about 5.2 eV and a conductive material with a work function in a range of about 3.8 eV to about 4.4 eV.

An NMOS gate structure 252a may be formed in the NMOS transistor area (a) and a PMOS gate structure 252b may be formed in the PMOS transistor area (b). The NMOS gate structure 252a may include a silicate layer (k), a high-k dielectric layer pattern 105a and the second gate electrode layer pattern 250a. The PMOS gate structure 252b may include a silicate layer (k), a high-k dielectric layer pattern 105a, the first gate electrode layer pattern 108a and the second gate electrode layer pattern 250a. Therefore, dual gate structures may be formed on the substrate 101. The dual gate structures may have threshold voltages sufficient for use in a semiconductor memory device, even though the dual gate structures include gate insulation layers including high-k dielectric materials. Particularly, polysilicon depletion may not occur in the PMOS transistor because the gate electrode of the PMOS transistor includes a metal compound.

Referring to FIG. 18, spacers 117 may be formed on sidewalls of the NMOS and the PMOS gate structures 252a and 252b, respectively. NMOS source/drain regions 118 may be formed at portions of the first channel region 103 adjacent to the NMOS gate structure 252a by implanting N-type impurities. PMOS source/drain regions 119 may be formed at portions of the second channel region 104 adjacent to the PMOS gate structure 252b by implanting P-type impurities. As a result, a CMOS transistor having dual gate structures may be formed on the substrate 101.

FIGS. 19 to 23 are cross-sectional views illustrating methods of manufacturing a gate structure in a semiconductor device according to some embodiments of the present invention. In FIGS. 19 to 23, “a” and “b” represent the NMOS and PMOS transistor areas, respectively, of the semiconductor substrate 101.

Referring to FIG. 19, active regions of the semiconductor substrate 101 are defined by the formation of an isolation layer 102. A first channel region 103 is formed in the active region of the NMOS transistor area (a) and a second channel region 104 is formed in the active region of the PMOS transistor area (b). The first channel region 103 may be formed by doping P-type impurities whereas the second channel region 104 may be formed by doping N-type impurities.

A silicate layer (k) and a high-k dielectric layer 105 may be sequentially formed on the semiconductor substrate 101 having the NMOS transistor area (a) and the PMOS transistor area (b). In some embodiments of the present invention, the silicate layer (k) may be omitted in order to simplify manufacturing processes for the semiconductor device. In some embodiments, the high-k dielectric layer 105 may be formed using a high-k material such as tantalum oxide, titanium oxide, zirconium oxide, hafnium silicon oxynitride, zirconium silicon oxynitride, aluminum oxide, aluminum oxynitride, hafnium aluminum oxide, yttrium oxide, niobium oxide, cesium oxide, indium oxide, lanthanum oxide, BST, PZT, strontium titanium oxide, lead titanium oxide, strontium ruthenium oxide, calcium ruthenium oxide, PLZT, SCR, and the like. The materials can be used alone or in any combination thereof. In some embodiments of the present invention, the high-k dielectric layer 105 may have a laminate structure that includes at least two films formed using the high-k materials.

In some embodiments, a tantalum carbon nitride layer 107 may be formed on the high-k dielectric layer 105. The tantalum carbon nitride layer 107 may be formed by providing a source gas that includes a tantalum metal complex onto the high-k dielectric layer 105 and then thermally decomposing the tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex is TAIMATA®.

In some embodiments of the present invention, a carrier gas and a pressure control gas may be provided in the formation of the tantalum carbon nitride layer 107. The carrier gas may introduce the source gas onto the semiconductor substrate 101 having the high-k dielectric layer 105 thereon. The pressure control gas may adjust the internal pressure of the process chamber wherein the semiconductor substrate 101 is loaded during forming the tantalum carbon nitride layer 107. In some embodiments, the carrier gas and the pressure control gas may be supplied through different gas supply lines. Each of the carrier gas and the pressure control gas may include an inert gas such as argon, helium, nitrogen and the like.

The tantalum carbon nitride layer 107 may be relatively thin so as to readily form a tantalum carbon nitride layer pattern by an etching process. For example, in some embodiments, the tantalum carbon nitride layer 107 may have a thickness in a range of about 30 Å to about 1,000 Å. The process for forming the tantalum carbon nitride layer 107 may be substantially the same as that described with reference to FIG. 6.

In some embodiments of the present invention, the tantalum carbon nitride layer 107 may be formed using a source gas that includes TAIMATA® by a CVD process, a PECVD process, an ALD process or a RAALD process. In some embodiments, a reaction gas used in forming the tantalum carbon nitride layer 107 may include NH₃, N₂, H₂, SiH₄, Si₂H₆, and the like. The gases may be used alone or in any combination thereof.

In some embodiments of the present invention, a gas for adjusting the carbon content in the tantalum carbon nitride layer 107 may be introduced into a chamber where the substrate 101 is loaded. Gases used to adjust the content of carbon may include, for example, CH₄ or C₂H₂. The gases may be used alone or in any combination thereof.

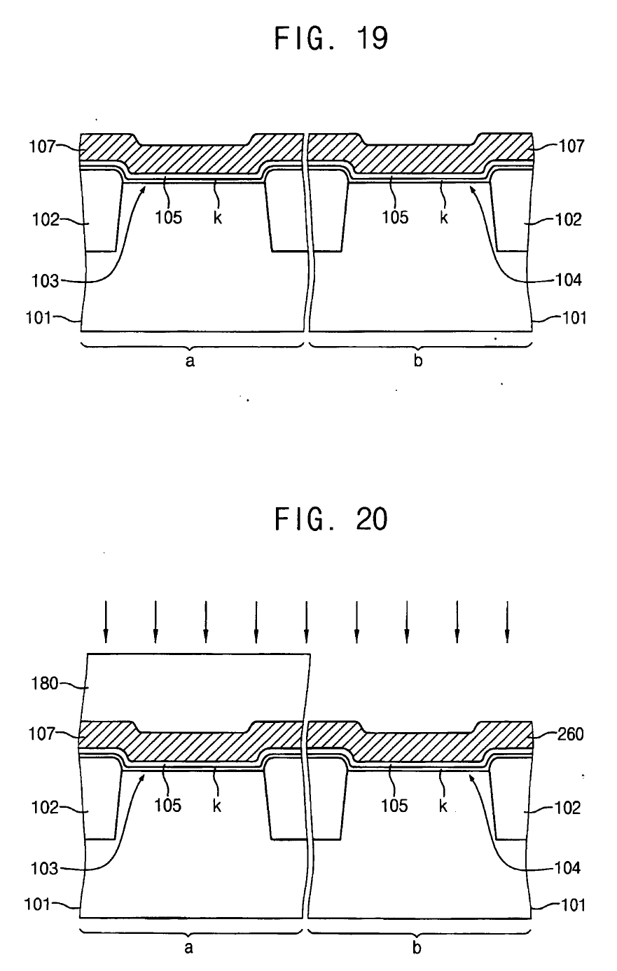

Referring to FIG. 20, a photoresist pattern 180 may be formed on the tantalum carbon nitride layer 107. The photoresist pattern 180 may selectively expose a portion of the tantalum carbon nitride layer 107 in the PMOS transistor area (b).

Nitrogen ions may be implanted into the exposed portion of the tantalum carbon nitride layer 107 so that the exposed portion of the tantalum carbon nitride layer 107 is transformed to a tantalum carbon nitride layer 260 having a greater nitrogen content (hereinafter referred to as the “nitrogen rich tantalum carbon nitride layer 260”).

In some embodiments of the present invention, an annealing process may be performed on the nitrogen rich tantalum carbon nitride layer 260 to activate the nitrogen rich tantalum carbon nitride layer 260 after implanting the nitrogen ions.

Since the work function of the tantalum carbon nitride layer 107 may increase as the content of nitrogen in the tantalum carbon nitride layer 107 increases, the nitrogen rich tantalum carbon nitride layer 260 may have a work function substantially higher than that of the tantalum carbon nitride layer 107.

In some embodiments, the photoresist pattern 180 may be removed through an ashing process and/or a stripping process.

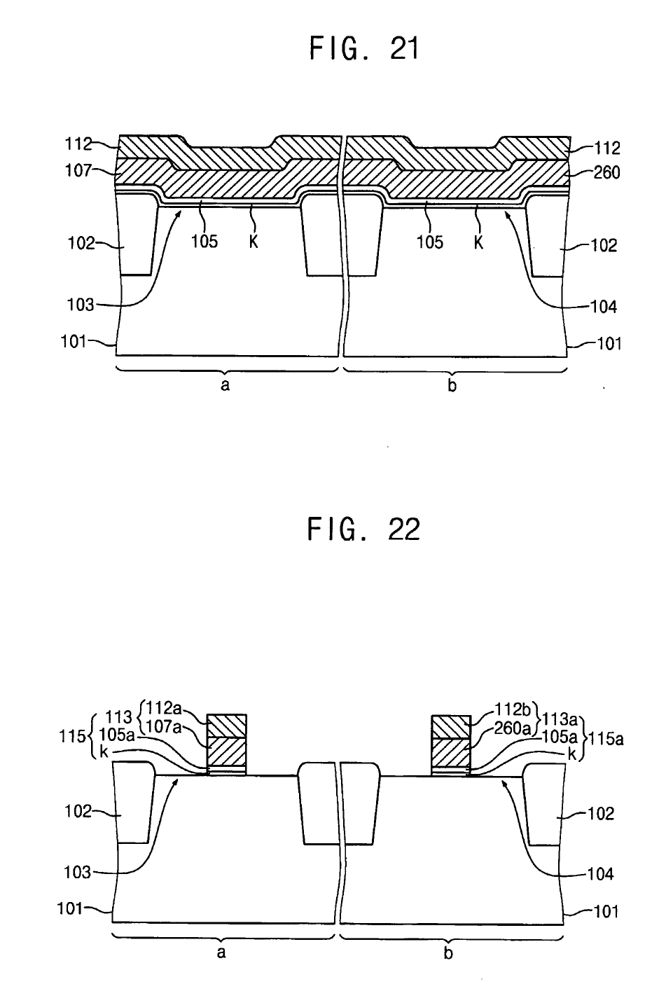

Referring to FIG. 21, a conductive layer 112 may be formed on the tantalum carbon nitride layer 107 and the nitrogen rich tantalum carbon nitride layer 260. In some embodiments, the conductive layer 112 may be formed with a metal or metal silicide, for example, tungsten, tantalum, titanium, titanium silicide, tungsten silicide, cobalt silicide, tantalum silicide, and the like.

To reduce the total resistance of the gate structures, in some embodiments, the conductive layer 112 may be formed with a conductive material having a specific resistance substantially lower than that of the tantalum carbon nitride layer 107 and the nitrogen rich tantalum carbon nitride layer 260.

In some embodiments of the present invention, the conductive layer 112 may be formed using doped polysilicon so that the conductive layer 112 may be readily patterned and that processes for forming a contact may be easily performed.

Referring to FIG. 22, the conductive layer 112, the tantalum carbon nitride layer 107, the high-k dielectric layer 105 and the silicate layer (k) may be sequentially etched to form an NMOS gate structure 115 on the first channel region 103. Simultaneously, a PMOS gate structure 115a may be formed on the second channel region 104 by continuously patterning the conductive layer 112, the nitrogen rich tantalum carbon nitride layer 260, the high-k dielectric layer 105 and the silicate layer (k).

The NMOS gate structure 115 includes a silicate layer pattern (k), a high-k dielectric layer pattern 105a, a tantalum carbon nitride layer pattern 107a and an NMOS conductive layer pattern 112a sequentially formed on the first channel region 103. The PMOS gate structure 115a includes a silicate layer pattern (k), a high-k dielectric layer pattern 105a, a nitrogen rich tantalum carbon nitride layer pattern 260a and a PMOS conductive layer pattern 112b sequentially formed on the second channel region 104.

A PMOS gate electrode 113a may include the nitrogen rich tantalum carbon nitride layer pattern 260a and the PMOS conductive layer pattern 112b. An NMOS gate electrode 113 may include the tantalum carbon nitride layer pattern 107a and the NMOS conductive layer pattern 112a.

As described above, the nitrogen rich tantalum carbon nitride layer 260 may be selectively formed by injecting the nitrogen ions into the tantalum carbon nitride layer 107. The tantalum carbon nitride layer 107 and the nitrogen rich tantalum carbon nitride layer 260 may be patterned to form the dual gate structures such as the NMOS and the PMOS gate structures 115 and 115a, respectively. Thus, processes for forming dual gate structures may be simplified to thereby improve the productivity of the semiconductor device.

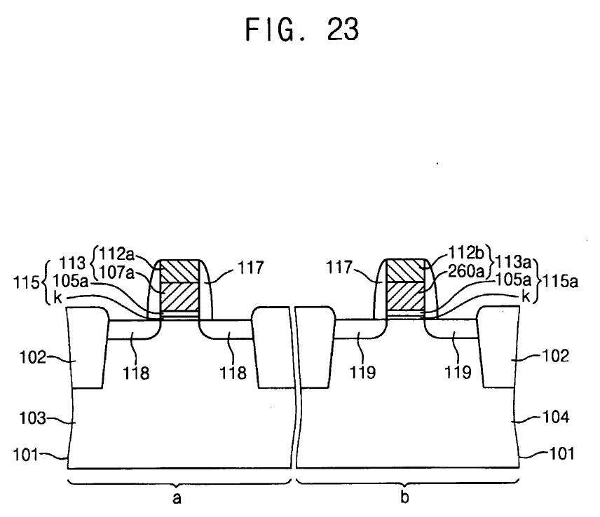

Referring to FIG. 23, spacers 117 may be formed on side walls of the NMOS and the PMOS gate structures 115 and 115a, respectively. N-type impurities may be implanted into portions of the first channel region 103 adjacent to the NMOS gate structure 115, thereby forming NMOS source/drain regions 118 in the first channel region 103. Additionally, P-type impurities may be implanted into the portions of the second channel region 104 adjacent to the PMOS gate structure 115a so that PMOS source/drain regions 119 may be formed in the second channel region 104.

Hereinafter, methods of forming a dual gate structure in a semiconductor device using a damascene process, according to some embodiments of the invention, will be described in detail with reference to the accompany drawings.

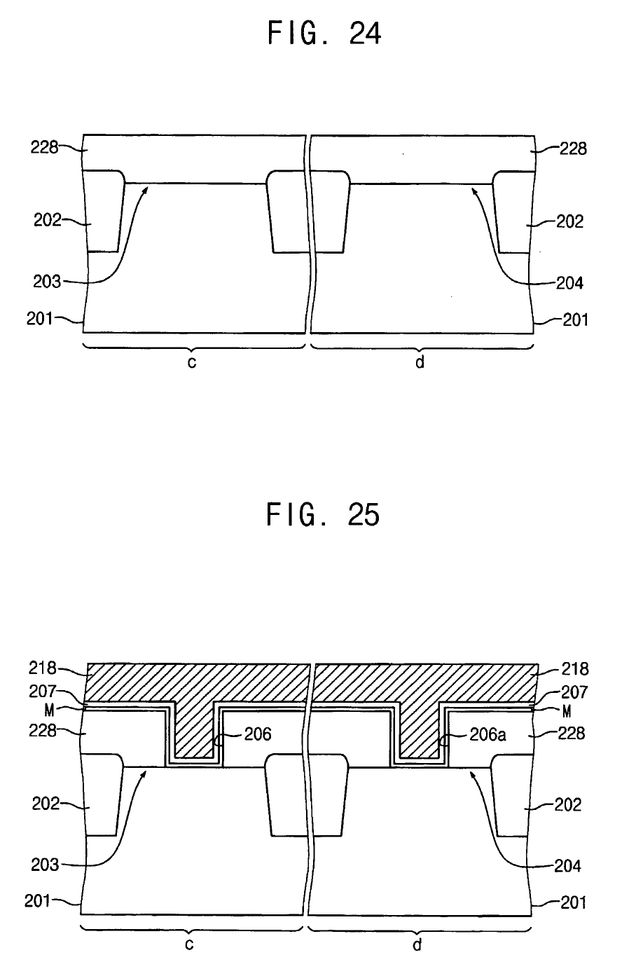

FIGS. 24 to 28 are cross-sectional views illustrating methods of manufacturing a gate structure in a semiconductor device according to some embodiments of the present invention. In FIGS. 24 to 28, “c” and “d” indicate an NMOS and a PMOS transistor area, respectively.

Referring to FIG. 24, active regions may be defined on a semiconductor substrate 201 by forming an isolation layer 202 on the semiconductor substrate 201.

P-type impurities may be implanted into the active region in the NMOS transistor area (c) to form a first channel region 203 in the NMOS transistor area (c). N-type impurities may be doped into the active region on the PMOS transistor area (d) so that a second channel region 204 is formed in the PMOS transistor area (d). The processes for forming the first and the second channel regions 203 and 204 may be substantially the same as those described with reference to FIG. 14 or FIG. 19.

A mold insulation layer 228 may be formed on the semiconductor substrate 201 having the NMOS transistor area (c) and the PMOS transistor area (d). The mold insulation layer 228 may be-formed using silicon oxide through a CVD process.

Referring to FIG. 25, the mold insulation layer 228 may be partially etched to form an NMOS gate opening 206 that partially exposes the first channel region 203 and to simultaneously form a PMOS gate opening 206a that partially exposes the second channel region 204.

A conformal silicate layer (M) and a high-k dielectric layer 207 may be formed on the mold insulation layer 228, on sidewalls of the NMOS and the PMOS gate openings 206 and 206a, and on the exposed portions of the first and the second channel regions 203 and 204.

A tantalum carbon nitride layer 218 may be formed on the high-k dielectric layer 207. The tantalum carbon nitride layer 218 may be formed by providing a source gas that includes a tantalum metal complex onto the high-k dielectric layer 207 and then thermally decomposing the tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex is TAIMATA®.

In some embodiments of the present invention, a carrier gas and a pressure control gas may be provided during the formation of the tantalum carbon nitride layer 218. The carrier gas may provide the source gas onto the semiconductor substrate 201 having the high-k dielectric layer 207 thereon. The pressure control gas may adjust the internal pressure of the process chamber wherein the semiconductor substrate 201 is loaded during forming the tantalum carbon nitride layer 218. In some embodiments, the carrier gas and the pressure control gas may be supplied through different gas supply lines. Each of the carrier gas and the pressure control gas may include an inert gas such as argon, helium, nitrogen, and the like. The process for forming the tantalum carbon nitride layer 218 may be substantially the same as that described with reference to FIG. 14 or FIG. 19.

In some embodiments of the present invention, the tantalum carbon nitride layer 218 may be formed using a source gas that includes TAIMATA® by a CVD process, a PECVD process, an ALD process or a RAALD process. A reaction gas used in forming the tantalum carbon nitride layer 107 may include, for example, NH₃, N₂, H₂, SiH₄, Si₂H₆, and the like. The reaction gases may be used alone or in any combination thereof.

In some embodiments of the present invention, a gas for adjusting the carbon content of the tantalum carbon nitride layer 218 may be introduced into the chamber wherein the substrate 201 is loaded. The gas for adjusting the content of carbon may include, for example, CH₄ or C₂H₂. The gases may be used alone or in any combination thereof.

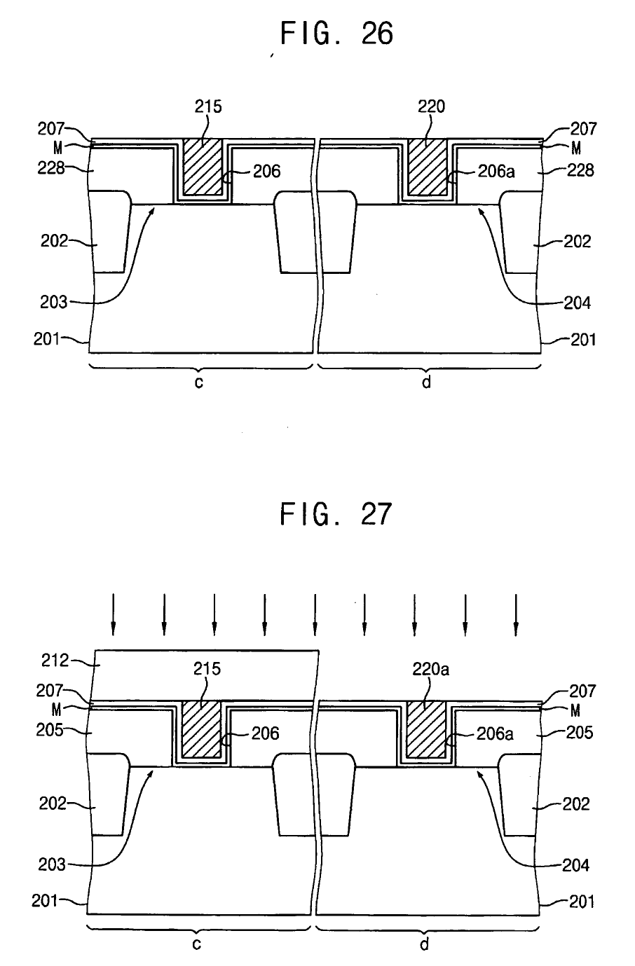

Referring to FIG. 26, the tantalum carbon nitride layer 218 may be partially removed until the high-k dielectric layer 207 positioned on the mold insulation layer 228 is exposed. Thus, an NMOS gate electrode 215 and a preliminary PMOS gate electrode 220 may be formed in the NMOS gate opening 206 and the PMOS gate opening 206a, respectively.

Referring to FIG. 27, a photoresist pattern 212 may be formed in the NMOS transistor area (c) so that the PMOS transistor area (d) is selectively exposed. Hence, the preliminary gate electrode 220 may be exposed by the photoresist pattern 212.

A PMOS gate electrode 220a may be formed in the PMOS transistor area (d) by implanting nitrogen ions into the resultant structure formed on the second channel region 204. Thus, the PMOS gate electrode 220a includes nitrogen rich tantalum carbon nitride. Hence, the PMOS gate electrode 220a may have a work function substantially higher than that of the NMOS gate electrode 215.

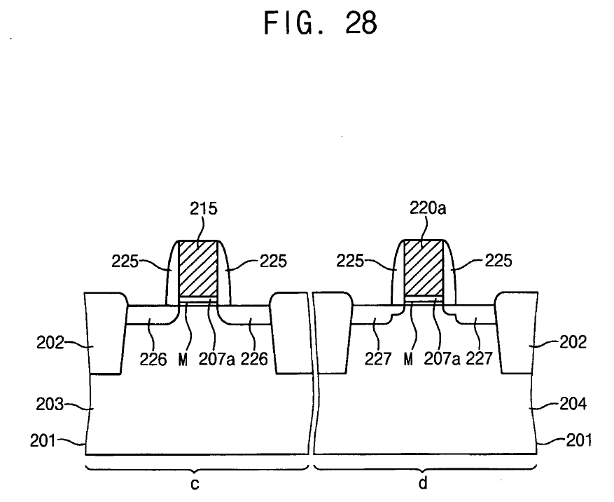

Referring to FIG. 28, the mold insulation layer 228, a portion of the high-k dielectric layer 207 and a portion of the silicate layer (M) are removed from the semiconductor substrate 201. The mold insulation layer 228, the portion of the high-k dielectric layer 207 and the portion of the silicate layer (M) may be etched by an isotropic etching process.

High-k dielectric layer patterns 207a may be formed between the NMOS gate electrode 215 and the exposed portion of the first channel region 203 and between the PMOS gate electrode 220a and the exposed portion of the second channel region 204.

Spacers 225 may be formed on the sidewalls of the NMOS and the PMOS gate electrodes 215 and 220a, and NMOS source/drain regions 226 may be formed at portions of the first channel region 203 adjacent to the NMOS gate electrode 215. Then, PMOS source/drain regions 227 may be formed at portions of the second channel region 204 adjacent to the PMOS gate electrode 220a.

Hereinafter, a capacitor in a semiconductor device, according to some embodiments of the present invention, will be described in detail.

In some embodiments of the present invention, a capacitor on a semiconductor substrate may be formed when a source gas including a tantalum metal complex is provided onto a semiconductor substrate. The tantalum metal complex may be thermally decomposed to form a first electrode including tantalum carbon nitride on the substrate. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex may be TAIMATA®.

In some embodiments of the present invention, a carrier gas and a pressure control gas may be provided in the formation of the first electrode. The carrier gas may provide the source gas onto the semiconductor substrate having the dielectric layer thereon. The pressure control gas may adjust the internal pressure of the process chamber in which the semiconductor substrate is loaded during forming the first electrode. In some embodiments, the carrier gas and the pressure control gas may be supplied through different gas supply lines. Each of the carrier gas and the pressure control gas may include an inert gas such as argon, helium, nitrogen and the like. The process for forming a first electrode that includes tantalum carbon nitride may be substantially the same as the process described above with reference to forming a tantalum carbon nitride layer.

After a dielectric layer is formed on the first electrode, a second electrode may be formed on the dielectric layer. In some embodiments, the second electrode may be formed using doped polysilicon, ruthenium, platinum, iridium, titanium nitride, tantalum nitride, tungsten nitride, tantalum carbon nitride, and the like. The materials can be used alone or in any combination thereof.

In some embodiments of the present invention, the first electrode may be formed using doped polysilicon, ruthenium, platinum, iridium, titanium nitride, tantalum nitride, tungsten nitride, tantalum carbon nitride, and the like. The materials can be used alone or in any combination thereof. In addition, the second electrode may be formed by providing a source gas including a tantalum metal complex, and then thermally decomposing the tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex may be TAIMATA®.

In some embodiments of the present invention, a carrier gas and a pressure control gas may be provided in the formation of the second electrode. The carrier gas may provide the source gas onto the semiconductor substrate having the dielectric layer thereon. The pressure control gas may adjust the internal pressure of the process chamber wherein the semiconductor substrate is loaded during forming the second electrode. In some embodiments, the carrier gas and the pressure control gas may be supplied through different gas supply lines. Each of the carrier gas and the pressure control gas may include an inert gas such as argon, helium, nitrogen, and the like.

The capacitor may have an electrode including tantalum carbon nitride with a high work function so that the leakage current from the capacitor is decreased. Further, the capacitor may include a dielectric layer having a high dielectric constant because at least one electrode of the capacitor includes tantalum carbon nitride, thereby improving the capacitance of the capacitor.

In some embodiments of the present invention, the tantalum metal complex may have a vapor phase created by using a bubbler or a liquid delivery system (LDS).

In some embodiments of the present invention, a post-treatment process may be executed on the first electrode. For example, the post-treatment process for the first electrode may be carried out using low or high frequency plasma. Here, the low or the high frequency plasma may be activated by a remote plasma process or a direct plasma process. The low or high frequency plasma may be generated from, for example, H₂, N₂, NH₃, SiH₄, Si₂H₆, and the like. The gases can be used alone or in any combination thereof. The post-treatment process for the first electrode may be performed to remove impurities from the first electrode and to control the amount of carbon and nitrogen in the first electrode. In the remote plasma process, a high frequency plasma may be introduced into the chamber wherein the substrate is loaded after the high frequency plasma is generated from an outside of the chamber. In the direct plasma process, the high frequency plasma may be directly generated over the substrate in the chamber.

A dielectric layer may be formed on the first electrode. In some embodiments, the dielectric layer may be formed using a metal oxide. For example, the dielectric layer may be formed using tantalum oxide, titanium oxide, zirconium oxide, hafnium silicon oxynitride, zirconium silicon oxynitride, aluminum oxide, aluminum oxynitride, hafnium aluminum oxide, yttrium oxide, niobium oxide, cesium oxide, indium oxide, lanthanum oxide, BST, PZT, strontium titanium oxide, lead titanium oxide, strontium ruthenium oxide, calcium ruthenium oxide, PLZT, SCR, and the like. The materials can be used alone or in any combination thereof. In some embodiments, the dielectric layer may have a single layer structure including a metal oxide. Alternatively, in some embodiments, the dielectric layer may have a multi-layer structure that includes at least two films of a metal oxide. Further, the dielectric layer may include a composite film including a metal oxide.

A second electrode may be formed on the dielectric layer. In some embodiments, the second electrode may be formed using doped polysilicon, ruthenium, platinum, iridium, titanium nitride, tantalum nitride, tungsten nitride, tantalum carbon nitride, and the like. The materials can be used alone or in any combination thereof.

When the second electrode includes tantalum carbon nitride, the second electrode may be formed by a process substantially the same as that for forming the first electrode. When the second electrode includes one of the above materials described above with reference to the first electrode, a capping layer may be additionally formed on the second electrode. In some embodiments, the capping layer may be formed using tantalum carbon nitride.

As a result, a capacitor having a first electrode, a dielectric layer and a second electrode may be formed on the substrate. The first electrode and the second electrode may correspond to a lower electrode and an upper electrode, respectively. For example, the first electrode may correspond to a storage electrode in a semiconductor memory device and the second electrode may correspond to a plate electrode in the semiconductor memory device.

Since the first electrode and/or the second electrode include tantalum carbon nitride, the dielectric layer including a high-k metal oxide may be advantageously employed in the capacitor. Thus, the capacitor may have a large capacitance and may also have reduced leakage current due to the high work functions of the first and/or second electrode.

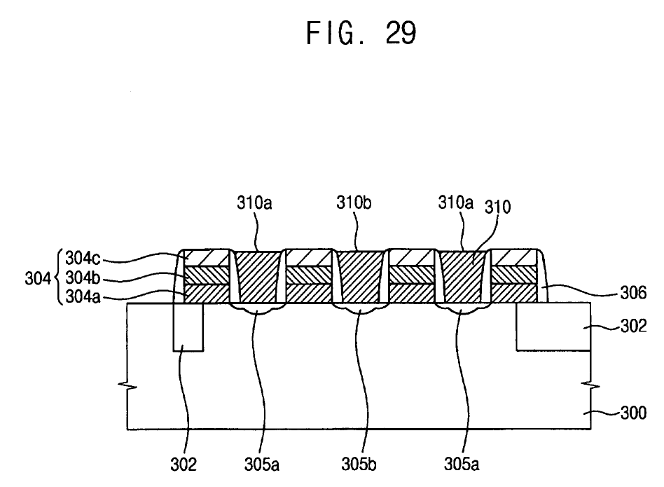

FIGS. 29 to 33 are cross-sectional views illustrating methods of manufacturing a capacitor in a semiconductor device according to embodiments of the present invention. In FIGS. 29 to 33, the capacitor may be advantageously employed in a dynamic random access memory (DRAM) device.

Referring to FIG. 29, a trench isolation layer 302 may be formed on a semiconductor substrate 300 through an isolation process such as a shallow trench isolation process. When the trench isolation layer 302 is formed on the substrate 300, the substrate is divided into an active region and a field region.

Gate structures 304 may be formed on the active region of the substrate 300. Each of the gate structures 304 may include a gate insulation layer (not shown) pattern, a polysilicon layer pattern 304a, a tungsten silicide layer pattern 304b and a silicon nitride layer pattern 304c. The gate structures 304 may serve as word lines of the DRAM device. Each gate electrode of the gate structures 304 may have a polycide structure that includes the polysilicon layer pattern 304a and the tungsten silicide layer pattern 304b. In some embodiments, the polysilicon layer pattern 304a may be highly doped with impurities.

Spacers 306 may be formed on sidewalls of the gate structures 304. In some embodiments, the spacers 306 may be formed using silicon nitride.

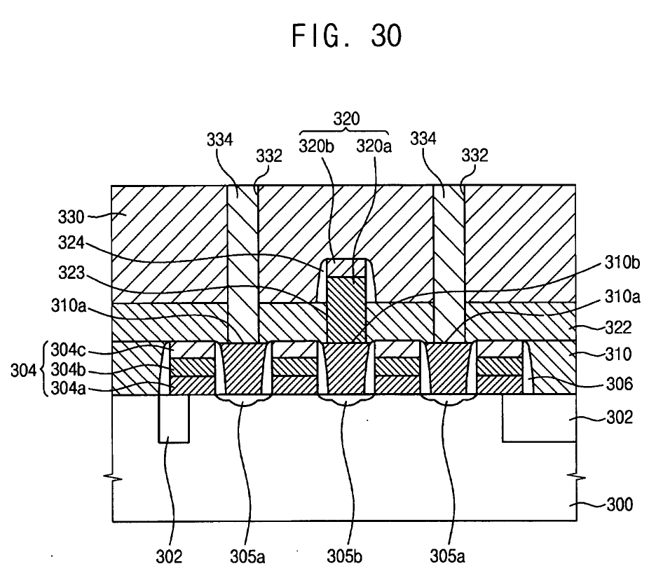

Using the gate structures 304 as implantation masks, impurities may be implanted into portions of the active region adjacent to the gate structures 304 so that source/drain regions 305a and 305b are formed in the active region. Thus, transistors having the gate structures 304 and the source/drain regions 305a and 305b are formed on the substrate 300. One of the source/drain regions 305a and 305b may correspond to a capacitor contact region with which a lower electrode of a capacitor makes contact. The other of the source/drain regions 305a and 305b may correspond to a bit line contact region with which a bit line structure 320 (see FIG. 30) makes contact. For example, in some embodiments, the source region 305a may serve as the capacitor contact region whereas the drain region 305b may serve as the bit line contact region.

A first insulating interlayer 310 may be formed on the substrate 300 to cover the gate structures 304, and the first insulating interlayer 310 may be partially etched to form self-aligned contact holes that expose the capacitor contact region and the bit line contact region.

A capacitor contact pad 310a and a bit line contact pad 310b may be formed in the self-aligned contact holes by filling the self-aligned contact holes with doped polysilicon. The capacitor contact pad 310a and the bit line contact pad 310b may make contact with the lower electrode of the capacitor and the bit line structure 320, respectively. Additionally, the capacitor contact pad 310a and the bit line contact pad 310b may be formed on the capacitor contact region and the bit line contact region, respectively.

Referring to FIG. 30, the bit line structure 320 may be formed on a second insulating interlayer 322. The bit line structure 320 may be electrically connected to the bit line contact pad 310b. Particularly, the second insulating interlayer 322 may be formed on the first insulating interlayer 310, the gate structures 304, the capacitor contact pad 310a and the bit line contact pad 310b. The second insulating interlayer 322 may be partially etched by a photolithography process to form a bit line contact hole 323 exposing the bit line contact pad 310b. A tungsten layer-may be formed on the second insulating interlayer 322 to fill up the bit line contact hole 323. In some embodiments, the bit line contact hole 323 may be completely filled with the tungsten layer. A silicon nitride layer may be formed on the tungsten layer 320a. When the silicon nitride layer and the tungsten layer are patterned, the bit line structure 320 having a tungsten layer pattern 320a and a silicon nitride layer pattern 320b may be formed on the bit line contact pad 310b.

An additional silicon nitride layer may be formed on the second insulating interlayer 322 to cover the bit line structure 320. The additional silicon nitride layer may be etched to thereby form a bit line spacer 324 on the sidewall of the bit line structure 320. The tungsten layer pattern 320a may be enclosed by the silicon nitride layer pattern 320b and the bit line spacer 324.

A third insulating interlayer 330 may be continuously formed on the bit line structure 320, the bit line spacer 324 and the second insulating interlayer 322. In some embodiments, the third insulating interlayer 330 may be formed using silicon oxide through a high density plasma process.

The third insulating interlayer 330 and the second insulating interlayer 322 may be partially etched to form a capacitor contact hole 332 that exposes the capacitor contact pad 310a.

A conductive layer may be formed on the third insulating interlayer 330 to fill up the capacitor contact hole 332, and then the conductive layer may be partially removed until the third insulating interlayer 330 is exposed. Thus, a lower electrode contact 334 may be formed on the capacitor contact pad 310a. In some embodiments, the conductive layer may be formed using metal or doped polysilicon.

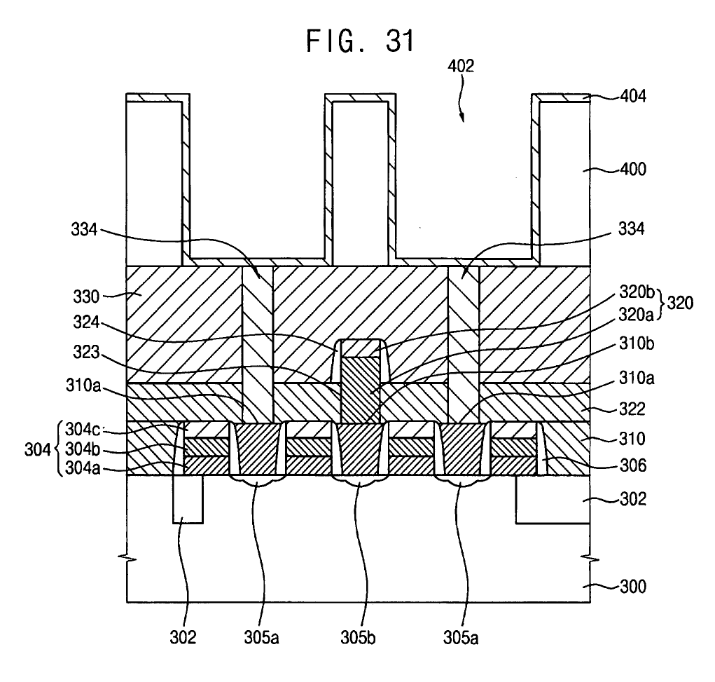

Referring to FIG. 31, an etch stop layer (not shown) may be formed on the lower electrode contact 334 and on the third insulating interlayer 330. The etch stop layer may be formed using a material that has an etching selectivity to the third insulating interlayer 330. For example, the etch stop layer may be formed using silicon nitride or silicon oxynitride.

A mold layer 400 may be formed on the etch stop layer. In some embodiments, the mold layer 400 may be formed using an oxide. The mold layer 400 and the etch stop layer may be partially etched to form an opening 402 that exposes the lower electrode contact 334. In the formation of the opening 402, the mold layer 400 may be partially removed until the etch stop layer is exposed, and then the etch stop layer may be partially removed to expose the lower electrode contact 334.

A first electrode layer 404 may be formed on the mold layer 400, the sidewall of the opening 402, the third insulating layer 330 and the lower electrode contact 334. The first electrode layer 404 may be formed by providing a source gas that includes a tantalum metal complex onto the mold layer 400 and then thermally decomposing the tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex is TAIMATA®.

In some embodiments of the present invention, a carrier gas and a pressure control gas may be provided in the formation of the first electrode layer 404. The carrier gas may provide the source gas onto the mold layer 400. The pressure control gas may adjust the internal pressure of the process chamber wherein the semiconductor substrate 301 is loaded during the formation of the first electrode layer 404. In some embodiments, the carrier gas and the pressure control gas may be supplied through different gas supply lines. Each of the carrier gas and the pressure control gas may include an inert gas such as argon, helium, nitrogen, and the like. The process for forming a first electrode layer 404 including tantalum carbon nitride may be substantially the same as that described above with reference to forming a tantalum carbon nitride layer.

When the first electrode layer 404 is formed using doped polysilicon, silicon atoms contained in the first electrode layer 404 may penetrate into a dielectric layer in the formation of the dielectric layer, thereby deteriorating the dielectric layer.

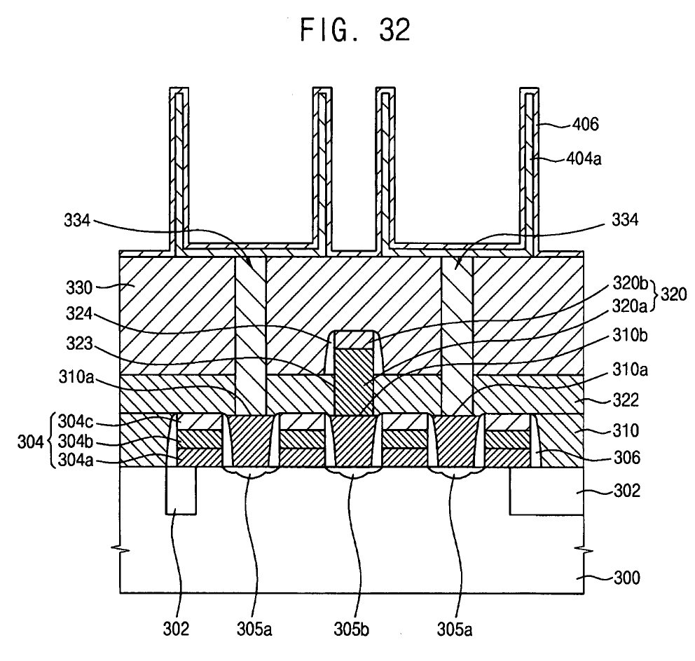

Referring to FIG. 32, a sacrificial layer (not shown) may be formed on the first electrode layer 404 to completely fill up the opening 402 is formed.

The sacrificial layer and the first electrode layer 404 may be partially removed until the mold layer 400 is exposed so that a first electrode layer pattern 404a on the lower electrode contact 334 and the sidewall of the opening 402. In some embodiments, the sacrificial layer and the first electrode layer 404 may be partially polished by a CMP process.

After the sacrificial layer and the mold layer 400 are removed, a high-k dielectric layer 406 may be formed on the first electrode layer pattern 404a. The high-k dielectric layer 406 may be formed using a high-k dielectric material.

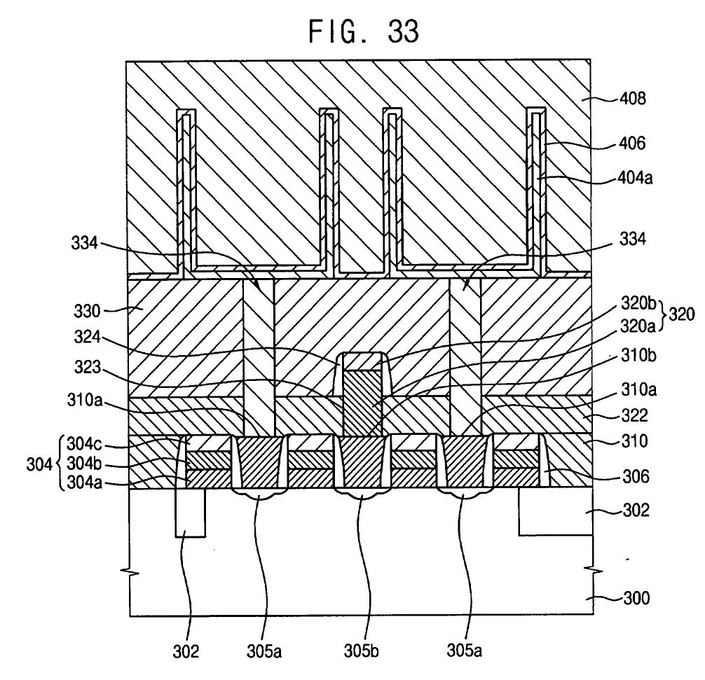

Referring to FIG. 33, a second electrode layer 408 may be formed on the high-k dielectric layer 406. In some embodiments, the second electrode layer 408 may be formed using tantalum carbon nitride, doped polysilicon, ruthenium, platinum, iridium, titanium nitride, tantalum nitride, tungsten nitride, and the like.

When the second electrode layer 408 is formed using tantalum carbon nitride, the second electrode layer 408 may be formed by a process substantially the same as the process for forming the first electrode layer 404.

In some embodiments of the present invention, a capping layer may be formed on the second electrode layer 408. In some embodiments, the capping layer may be formed using tantalum carbon nitride.

As described above, the capacitor may include a first lower electrode and/or a second electrode composed of tantalum carbon nitride so that the capacitor may advantageously include the high-k dielectric layer, thereby increasing the capacitance and reducing leakage current.

Hereinafter, methods of manufacturing a capacitor according to some embodiments of the present invention will be described.

After a mold layer having an opening for forming the capacitor is formed on a semiconductor substrate, a lower electrode layer may be formed on the mold layer, a sidewall of the opening and a bottom of the opening. The mold layer may be formed by a process substantially the same as the process described with reference to FIG. 31. In some embodiments, the lower electrode layer may be formed using ruthenium, platinum, iridium, titanium nitride, tungsten nitride tantalum nitride, and the like.

After a sacrificial layer is formed on the lower electrode layer to completely fill up the opening, the sacrificial layer and the lower electrode layer may be partially removed until the mold layer is exposed. Thus, a lower electrode may be formed on the sidewall and the bottom of the opening. In some embodiments, the lower electrode may be formed by a CMP process.

A high-k dielectric layer may be formed on the lower electrode after removing the mold layer and the sacrificial layer. The high-k dielectric layer may be formed using a high-k dielectric material.

An upper electrode layer may be formed on the high-k dielectric layer by providing-a source gas including a tantalum metal complex onto the high-k dielectric layer and then thermally decomposing the tantalum metal complex. The tantalum metal complex may include one or more ligands bound to a tantalum metal, wherein one or more of the ligands include nitrogen and one or more of the ligands include carbon. Thus, the tantalum metal complex may be an organometallic complex having one tantalum metal atom bound to ligands containing nitrogen and carbon. The tantalum metal complex may also include more than one tantalum metal atom.

In some embodiments of the present invention, the tantalum metal complex is a tantalum amine derivative. For example, the tantalum metal complex may be represented by a chemical formula of Ta(NR₁)(NR₂R₃)₃, wherein R₁, R₂ and R₃ are each independently H or an alkyl group, such as a C₁-C₆ alkyl. Thus, R₁, R₂ and R₃ may be the same as one another or different from one another. In some embodiments, the tantalum metal complex may be TAIMATA®.

In some embodiments of the present invention, a carrier gas and a pressure control gas may be provided in the formation of the upper electrode layer. The carrier gas may provide the source gas onto the high-k dielectric layer. The pressure control gas may adjust the internal pressure of the process chamber in which the substrate is loaded during the formation of the upper electrode layer. In some embodiments, the carrier gas and the pressure control gas may be supplied through different gas supply lines. Each of the carrier gas and the pressure control gas may include an inert gas such as argon, helium, nitrogen, and the like. The process for forming an upper electrode layer including tantalum carbon nitride may be substantially the same as that described with reference to forming a tantalum carbon nitride layer.

Since the capacitor includes an upper electrode composed of tantalum carbon nitride, the capacitor may have a large capacitance and reduced leakage current.

Evaluation of Characteristics of Gate Structures

Work functions of gate electrodes in gate structures were measured and the results were shown in Table 1, In Table 1, IA refers to the inversion accumulation and AI refers to the accumulation inversion. Additionally, Delta represents the difference between IA and AI. Delta may occur due to charge trapping sites of the oxide generated in accordance with the applied voltages. Delta may also be referred to as hysteresis. Flat band voltages (V_{fb}) of the gate structures were measured using IA and AI. The reference work function of titanium nitride is about 4.7 eV and the reference work function of tantalum nitride is about 4.1 eV.

TABLE 1

| | I A | A I [V] | Delta | Work function [eV] |
|---|---|---|---|---|
| P-TiN (Ti-rich) | −0.36 | −0.33 | 30 | 4.75 |
| P-TiN (N-rich) | −0.42 | −0.33 | 110 | 4.69 |
| P-TaN (Ta-rich) | −0.80 | −0.78 | 20 | 4.31 |
| P-TaN (N-rich) | −0.72 | −0.73 | 10 | 4.39 |
| P-Ta | −0.79 | −0.79 | 0 | 4.32 |
| A-TaN (100 Å) | −0.62 | −0.62 | 0 | 4.49 |
| A-TaN (200 Å) | −0.66 | −0.67 | 10 | 4.45 |
| C-TaN (200 Å) | −0.34 | −0.35 | 10 | 4.77 |
| A-TaN (400 Å) | −0.85 | −0.83 | 20 | 4.26 |
| Poly | −1.03 | −1.32 | 290 | 4.08 |

In Table 1, P—TiN and P—TaN refer to gate electrodes including titanium nitride and tantalum nitride, respectively, formed through PVD processes. A-TaN refer to gate electrodes including tantalum nitride formed through an ALD process, and C—TaN refers to gate electrodes including tantalum nitride formed through a CVD process. Poly refers to a gate electrode including doped polysilicon formed through a CVD process.

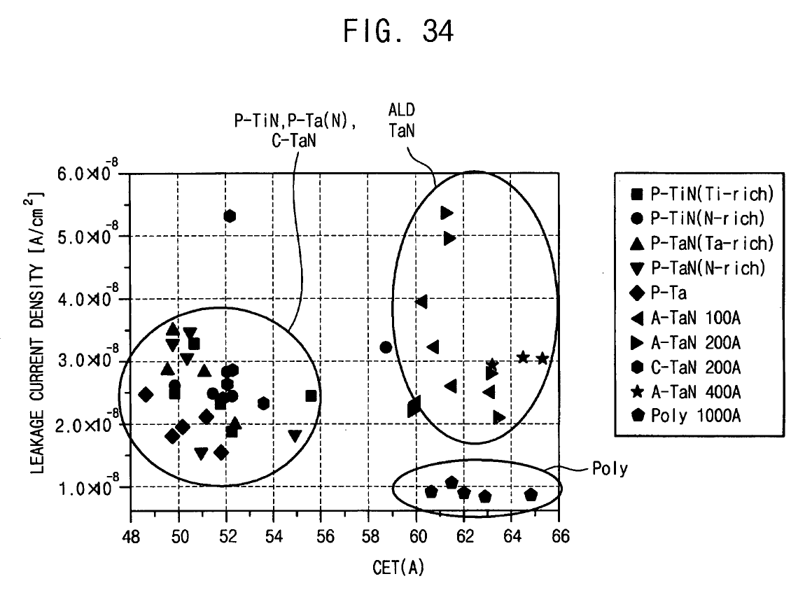

FIG. 34 is a graph illustrating the leakage current densities of gate structures according to some embodiments of the present invention.

As shown in FIG. 34, the gate structures may have good electrical characteristics when the capacitance, as measured by the equivalent oxide thickness (CET), and the leakage current densities are relatively low. As can be seen in FIG. 34, the A-TaN has CETs substantially greater than those of C—TaN.

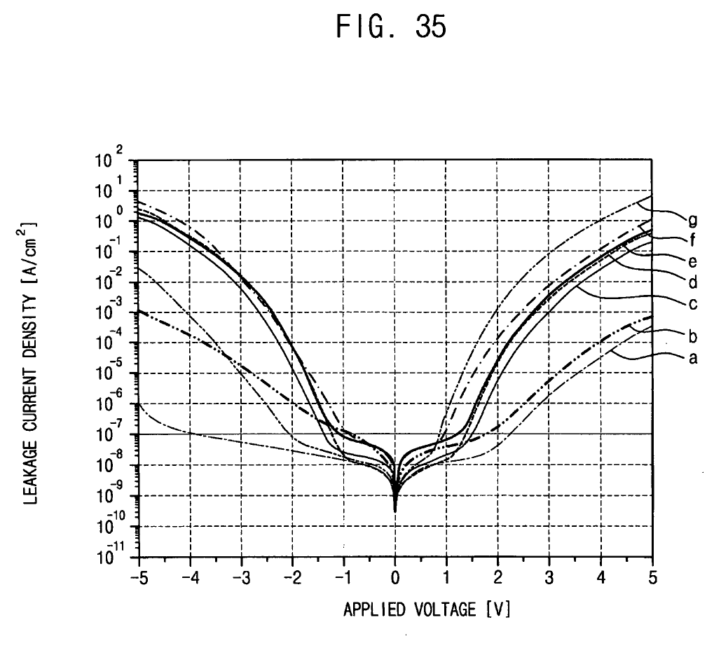

FIG. 35 is a graph illustrating leakage current densities of capacitors according to some embodiments of the present invention. In FIG. 35, the first curve (a) refers to a TaN layer of 200 Å (560° C.).±19.3 Å, the second curve (b) refers to a C—TaN layer of 200 Å±54.3 Å, and the third curve (c) refers to a TaN layer of 100 Å (250° C.)±24.8 Å. The fourth curve (d) refers to a TaN layer of 200 Å±26.9 Å, the fifth curve (e) refers to a TaN layer of 400 Å±24.6 Å, and the sixth curve (f) refers to a TiN layer of 200 Å (560° C.)±19.3 Å. The seventh curve (g) refers to a TiN layer of 200 Å (450° C.)±18.4 Å.

Referring to FIG, 35, a gate structure including the gate electrode of TaN may have a low leakage current density as shown the first curve (a).

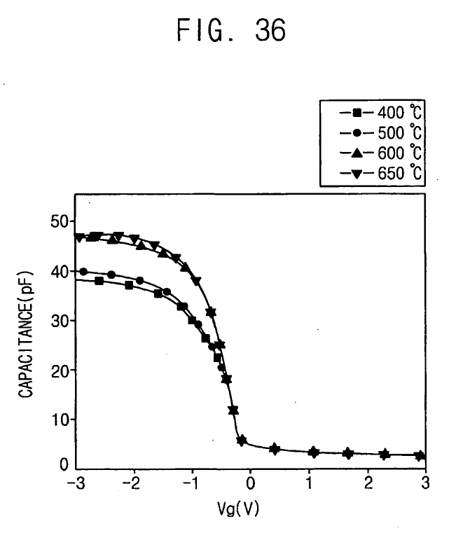

FIG. 36 is a graph illustrating the C—V characteristics of capacitors according to some embodiments of the present invention.

The capacitors included hafnium silicon oxynitride layers, tantalum carbon nitride layers and doped polysilicon layers sequentially formed on a substrate. The tantalum carbon nitride layers were formed using a source gas of TAIMATA® and a carrier gas of argon for bubbling and carrying the source gas. The tantalum carbon nitride layers were formed in a chamber that had a pressure of about 1 Torr. A pressure control gas was introduced into the chamber during the formation of the tantalum carbon nitride layers. The tantalum carbon nitride layers had thickness of about 50 Å.

Four sample capacitors including the tantalum carbon nitride layers were manufactured at temperatures of about 400° C., about 500° C., about 600° C. and about 650° C., respectively.

Referring to FIG. 36, as the formation temperature of the tantalum carbon nitride layer increased from about 400° C. to about 600° C., the capacitance of the capacitor increased. Table 2 shows equivalent oxide thickness (EOT) and flat band voltages (V_{fb}) of the sample capacitors.

TABLE 2

| Temperature | EOT | Vfb |
|---|---|---|
| 400° C. | 19.2 | −0.405 |
| 500° C. | 18.1 | −0.323 |
| 600° C. | 15.5 | −0.377 |
| 650° C. | 14.7 | −0.398 |

As shown in Table 2, the V_{fb} of the capacitors may vary according to the formation temperature of the tantalum carbon nitride layers. That is, the V_{fb} of the capacitors increased when the formation temperatures of the tantalum carbon nitride layers increased from about 400° C. to about 650° C. Additionally, the hafnium silicon oxynitride layers of the capacitors may vary as the formation temperature of the tantalum carbon nitride layers increases. Therefore, the electrical characteristics of the capacitors may be improved as the formation temperature of the tantalum carbon nitride layers increases.

According to some embodiments of the present invention, a tantalum carbon nitride layer may have a high work function and a low reactivity relative to a high-k dielectric layer.

When the tantalum carbon nitride layer is employed as a gate insulation layer of a MOS transistor, the gate electrode of the MOS transistor may have a relatively small EOT. Additionally, the tantalum carbon nitride layer may advantageously serve as a gate electrode of a PMOS transistor. Further, dual gate structures may be formed on a substrate by employing the tantalum carbon nitride layer.

When the tantalum carbon nitride layer is used as an electrode of a capacitor, the capacitor may advantageously include a high-k dielectric layer. Thus, in some embodiments, the capacitor may have a large capacitance and a low leakage current. Furthermore, a semiconductor device including the capacitor may have an improved reliability because the tantalum carbon nitride layer may prevent the high-k dielectric layer from deteriorating due to a reaction that may occur at the interface of the electrode and the high-k dielectric layer.

The foregoing is illustrative of the present invention and is not to be construed as limiting thereof. Although a few example embodiments of the present invention have been described, those skilled in the art will readily appreciate that many modifications are possible in the example embodiments without materially departing from the novel teachings and advantages of the present invention. Accordingly, all such modifications are intended to be included within the scope of the present invention as defined in the claims. In the claims, means-plus-function clauses are intended to cover the structures described herein as manufacturing the recited function, and not only structural equivalents but also equivalent structures.

What is claimed is:

1. A method of forming a tantalum carbon nitride layer comprising:
introducing a source gas comprising a tantalum metal complex onto a substrate, wherein one or more of the ligands of the tantalum metal complex comprise nitrogen and one or more of the ligands of the tantalum metal complex comprise carbon; and
thermally decomposing the tantalum metal complex to form a tantalum carbon nitride layer on the substrate.

2. The method of claim 1, wherein the tantalum metal complex comprises Ta(NR₁)(NR₂R₃)₃, wherein R₁, R₂ and R₃ are each independently H or a C₁-C₆ alkyl group.

3. The method of claim 2, wherein the tantalum metal complex comprises [Ta(═NC(CH₃)₂C₂H₅)(N(CH₃)₂)₃].

4. The method of claim 1, further comprising:
using a carrier gas to introduce the source gas onto the substrate; and
providing a pressure control gas to the substrate to adjust a pressure over the substrate during forming of the tantalum carbon nitride layer.

5. The method of claim 1, wherein thermally decomposing the tantalum metal complex is performed at a temperature in a range of about 400° C. to about 700° C. and at a pressure in a range of about 0.1 Torr to about 100 Torr.

6. The method of claim 1, further comprising introducing a reaction gas comprising nitrogen onto the tantalum carbon nitride layer to increase a nitrogen content of the tantalum carbon nitride layer.

7. The method of claim 1, further comprising introducing a reaction gas comprising carbon onto the tantalum carbon nitride layer to increase a carbon content of the tantalum carbon nitride layer.

8. The method of claim 1, further comprising treating the tantalum carbon nitride layer with a reaction gas activated by a remote plasma process or a direct plasma process, wherein the reaction gas comprises one selected from the group consisting of ammonia, hydrogen, nitrogen, silane, disilane and any combination thereof.

9. A method of forming a gate structure comprising:
forming a dielectric layer on a substrate;
introducing a source gas comprising a tantalum metal complex onto the dielectric layer, wherein one or more of the ligands of the tantalum metal complex comprise nitrogen and one or more of the ligands of the tantalum metal complex comprise carbon;
thermally decomposing the tantalum metal complex to form a tantalum carbon nitride layer on the dielectric layer; and
forming a gate electrode on the dielectric layer by patterning the tantalum carbon nitride layer.

10. The method of claim 9, wherein the tantalum metal complex comprises Ta(NR₁)(NR₂R₃)₃, wherein R₁, R₂ and R₃ are each independently H or a C₁-C₆ alkyl group.

11. The method of claim 10, wherein the tantalum metal complex comprises [Ta(═NC((CH₃)₂C₂H₅)(N(CH₃)₂)₃].

12. The method of claim 9, wherein the dielectric layer comprises at least one material selected from the group consisting of tantalum oxide (Ta₂O₅), titanium oxide (TiO₂), zirconium oxide (ZrO₂), hafnium silicon oxynitride (HfSi_{X}O_{Y}N_{Z}), zirconium silicon oxynitride (ZrSi_{X}O_{Y}N_{Z}), aluminum oxide (Al₂O₃), aluminum oxynitride (Al_{X}O_{Y}N_{Z}), hafnium aluminum oxide (HfAl_{X}O_{Y}), yttrium oxide (Y₂O₃), niobium oxide (Nb₂O₅), cesium oxide (CeO₂), indium oxide (InO₃), lanthanum oxide (LaO₂), BST [(Ba, Sr)TiO₃], PZT [(Pb, Zr)TiO₃], strontium titanium oxide (SrTiO₃), lead titanium oxide (PbTiO₃), strontium ruthenium oxide (SrRuTiO₃), calcium ruthenium oxide (CaRuTiO₃), PLZT [Pb(La, Zr)TiO₃] and SCR [(Sr, Ca)RuO₃].

13. The method of claim 9, wherein the tantalum carbon nitride layer has a work function in a range of about 4.6 eV to about 5.2 eV.

14. The method of claim 9, wherein the tantalum carbon nitride layer comprises about 5 to about 50 percent by weight of carbon based on a total weight of tantalum carbon nitride.

15. The method of claim 9, further comprising forming source/drain regions on portions of the substrate adjacent to the gate electrode by doping P-type impurities into the portions of the substrate.

16. The method of claim 9, further comprising:
using a carrier gas to introduce the source gas onto the dielectric layer; and
providing a pressure control gas onto the dielectric layer to adjust a pressure over the substrate during forming of the tantalum carbon nitride layer.

17. The method of claim 16, wherein the carrier gas comprises one selected from the group consisting of argon, helium, nitrogen and any combination thereof.

18. The method of claim 16, wherein the pressure control gas comprises one selected from the group consisting of argon, helium, nitrogen and any combination thereof.

19. The method of claim 9, wherein thermally decomposing the tantalum metal complex is performed at a temperature in a range of about 400° C. to about 700° C. and at a pressure in a range of about 0.1 Torr to about 100 Torr.

20. The method of claim 9, further comprising introducing a reaction gas comprising nitrogen onto the tantalum carbon nitride layer to increase a nitrogen content of the tantalum carbon nitride layer.

21. The method of claim 20, wherein the reaction gas comprises one selected from the group consisting of nitrogen, ammonia, hydrazine and any combination thereof.

22. The method of claim 9, further comprising introducing a reaction gas comprising carbon onto the tantalum carbon nitride layer to increase a carbon content of the tantalum carbon nitride layer.

23. The method of claim 22, wherein the reaction gas comprises methane, acetylene or any combination thereof.

24. The method of claim 9, further comprising treating the tantalum carbon nitride layer with a reaction gas activated by a remote plasma process or a direct plasma process, wherein the reaction gas comprises one selected from the group consisting of ammonia, hydrogen, nitrogen, silane, disilane and any combination thereof.

25. The method of claim 9, wherein the tantalum carbon nitride layer has a thickness in a range of about 20 Å to about 1,000 Å.

26. The method of claim 9, further comprising forming a conductive layer pattern on the gate electrode.

27. The method of claim 26, wherein the conductive layer pattern comprises at least one material selected from the group consisting of polysilicon doped with impurities, a metal and a metal silicide.

28. The method of claim 9, further comprising forming a mold layer pattern before forming the dielectric layer, wherein the mold layer pattern has an opening that exposes a portion of the substrate.

29. The method of claim 28, wherein forming the gate electrode further comprises
partially removing the tantalum carbon nitride layer and the dielectric layer until the mold layer pattern is exposed; and
removing the exposed mold layer pattern.

30. A method of manufacturing dual gate electrodes in a semiconductor device, comprising:
forming a dielectric layer on a substrate having a PMOS transistor area and an NMOS transistor area;
forming a first gate electrode on a first portion of the dielectric layer in the PMOS area of the substrate, wherein the first gate electrode comprises a tantalum carbon nitride layer pattern and a first conductive layer pattern; and
forming a second gate electrode on a second portion of the dielectric layer in the NMOS area of the substrate, wherein the second gate electrode comprises a second conductive layer pattern,
wherein forming of the tantalum carbon nitride layer pattern comprises introducing a source gas comprising a tantalum metal complex and thermally decomposing the tantalum metal complex, wherein one or more of the ligands of the tantalum metal complex comprise nitrogen and one or more of the ligands of the tantalum metal complex comprise carbon.

31. The method of claim 30, wherein the tantalum metal complex comprises Ta(NR₁)(NR₂R₃)₃, wherein R₁, R₂ and R₃ are each independently H or C₁-C₆ alkyl.

32. The method of claim 31, wherein the tantalum metal complex comprises [Ta(═NC((CH₃)₂C₂H₅))(N(CH₃)₂)₃].

33. The method of claim 30, wherein the dielectric layer comprises at least one material selected from the group consisting of tantalum oxide (Ta₂O₅), titanium oxide (TiO₂), zirconium oxide (ZrO₂), hafnium silicon oxynitride (HfSi_{X}O_{Y}N_{Z}), zirconium silicon oxynitride (ZrSi_{X}O_{Y}N_{Z}), aluminum oxide (Al₂O₃), aluminum oxynitride (Al_{X}O_{Y}N_{Z}), hafnium aluminum oxide (HfAl_{X}O_{Y}), yttrium oxide (Y₂O₃), niobium oxide (Nb₂O₅), cesium oxide (CeO₂), indium oxide (InO₃), lanthanum oxide (LaO₂), BST [(Ba, Sr)TiO₃], PZT [(Pb, Zr)TiO₃], strontium titanium oxide (SrTiO₃), lead titanium oxide (PbTiO₃), strontium ruthenium oxide (SrRuTiO₃), calcium ruthenium oxide (CaRuTiO₃), PLZT [Pb(La, Zr)TiO₃] and SCR [(Sr, Ca)RuO₃].

34. The method of claim 30, wherein the tantalum carbon nitride layer has a work function in a range of about 4.6 eV to about 5.2 eV.

35. The method of claim 30, further comprising:
using a carrier gas to introduce the source gas onto the dielectric layer; and
providing a pressure control gas onto the dielectric layer to adjust a pressure over the substrate during forming of the tantalum carbon nitride layer.

36. The method of claim 30, wherein the first and the second conductive layer patterns have work functions in a range of about 3.8 eV to about 4.4 eV, and the first and the second conductive layer patterns each independently comprise at least one material selected from the group consisting of a metal, a metal compound and a semiconductor material doped with impurities.

37. The method of claim 36, wherein the first and the second conductive layer patterns comprise at least one material selected from the group consisting of tantalum carbide, tantalum silicon nitride and tantalum.

38. A method of manufacturing a capacitor, comprising:
introducing a source gas comprising a tantalum metal complex onto a substrate, wherein one or more of the ligands of the tantalum metal complex comprise nitrogen and one or more of the ligands of the tantalum metal complex comprise carbon;
thermally decomposing the tantalum metal complex to form a first electrode comprising a tantalum carbon nitride layer on the substrate;
forming a dielectric layer on the first electrode; and
forming a second electrode on the dielectric layer.

39. The method of claim 38, wherein the tantalum metal complex comprises Ta(NR₁)(NR₂R₃)₃, wherein R₁, R₂ and R₃ are each independently H or C₁-C₆ alkyl.

40. The method of claim 39, wherein the tantalum metal complex comprises [Ta(═NC((CH₃)₂C₂H₅))(N(CH₃)₂)₃].

41. The method of claim 38, further comprising:
using a carrier gas to introduce the source gas to the dielectric layer; and
providing a pressure control gas onto the dielectric layer to adjust a pressure over the substrate during forming of the tantalum carbon nitride layer.

42. The method of claim 38, wherein the dielectric layer comprises a metal oxide.

43. The method of claim 38, wherein the dielectric layer comprises at least one material selected from the group consisting of tantalum oxide (Ta₂O₅), titanium oxide (TiO₂), zirconium oxide (ZrO₂), hafnium silicon oxynitride (HfSiₓO_{y}N_{z}), zirconium silicon oxynitride (ZrSi_{X}O_{Y}N_{Z}), aluminum oxide (Al₂O₃), aluminum oxynitride (Al_{X}O_{Y}N_{Z}), hafnium aluminum oxide (HfAl_{X}O_{Y}), yttrium oxide (Y₂O₃), niobium oxide (Nb₂O₅), cesium oxide (CeO₂), indium oxide (InO₃), lanthanum oxide (LaO₂), BST [(Ba, Sr)TiO₃], PZT [(Pb, Zr)TiO₃], strontium titanium oxide (SrTiO₃), lead titanium oxide (PbTiO₃), strontium ruthenium oxide (SrRuTiO₃), calcium ruthenium oxide (CaRuTiO₃), PLZT [Pb(La, Zr)TiO₃] and SCR [(Sr, Ca)RuO₃].

44. The method of claim 38, wherein the second electrode comprises tantalum carbon nitride formed by
introducing a source gas comprising a tantalum metal complex onto the dielectric layer, wherein one or more of the ligands of the tantalum metal complex comprises nitrogen and one or more of the ligands of the tantalum metal complex comprises carbon; and
thermally decomposing the tantalum metal complex to form the second electrode.

45. The method of claim 38, wherein the second electrode comprises a material selected from one or more of the group consisting of polysilicon doped with impurities, ruthenium, platinum, iridium, titanium nitride, tantalum nitride and tungsten nitride.
